(19) United States
(12) Patent Application Publication
(10) Pub. No.: US 2015/0357213 A1
(43) Pub. Date: Dec. 10, 2015

(54) SUBSTRATE ATTACHING/DETACHING UNIT FOR SUBSTRATE HOLDER, WET-TYPE SUBSTRATE PROCESSING APPARATUS INCLUDING THE SAME, SUBSTRATE HOLDER CONVEYING METHOD, SUBSTRATE PROCESSING APPARATUS, AND SUBSTRATE CONVEYING METHOD

(71) Applicant: EBARA CORPORATION, Tokyo (JP)

(72) Inventors: Toshio YOKOYAMA, Tokyo (JP); Masahiko SEKIMOTO, Tokyo (JP); Kenichi KOBAYASHI, Tokyo (JP)

(21) Appl. No.: 14/734,983

(22) Filed: Jun. 9, 2015

(30) Foreign Application Priority Data
Jun. 9, 2014 (JP) 2014-118553
Jul. 7, 2014 (JP) 2014-139693

(51) Int. Cl. H01L 21/67; H01L 21/677; H01L 21/02; H01L 21/687; H01L 21/311; B25J 11/00; H01L 21/68

(52) U.S. Cl. CPC H01L 21/67086; B25J 11/0095; H01L 21/67742; H01L 21/67751; H01L 21/68; H01L 21/687; H01L 21/31133; H01L 21/0206

(57) ABSTRACT

A substrate attaching/detaching unit includes a stocker accommodating a plurality of substrate holders 80 and adapted so that the substrate holders 80 are aligned in a vertical direction with one another in a horizontal posture, a first substrate holder conveying mechanism that takes the substrate holders 80 into and out of the stocker, an elevating mechanism that raises and lowers the first substrate holder conveying mechanism in the vertical direction, a second substrate holder conveying mechanism that transfers the substrate holder to and from the first substrate holder conveying mechanism, and a substrate attaching/detaching mechanism that attaches and detaches the substrate to and from the substrate holder held in the second substrate holder conveying mechanism.

### TECHNICAL FIELD

The present invention relates to a substrate attaching/detaching unit for a substrate holder, a wet-type substrate processing apparatus including the same, a substrate holder conveying method, a substrate processing apparatus, and a substrate conveying method.

### BACKGROUND ART

The present application claims priority from Japanese Patent Application No. 2014-118553 filed on Jun. 9, 2014 and No. 2014-139693 filed on Jul. 7, 2014, the entire contents of which are hereby incorporated by reference into this application.

Conventionally, a wiring has been formed in a fine wiring groove, a hole, or a resist opening provided on a surface of a semiconductor wafer, and a bump (projection-shaped electrode) electrically connected to an electrode of a package has been formed on the surface of the semiconductor wafer. Examples of a method for forming the wiring and the bump include an electrolytic plating method, an evaporation method, a printing method, and a ball bump method. In recent years, the electrolytic plating method in which a semiconductor chip can be refined and is relatively stable in performance as the number of inputs/outputs (I/Os) of a semiconductor chip increases and a pitch of the semiconductor chip is refined has been frequently used.

In a process for forming a wiring in a resist opening using the electrolytic plating method, the wiring is formed in the resist opening, and is than removed by stripping a resist formed on a substrate and etching a seed layer (or a barrier metal). The process for forming the wiring, a process for stripping the resist, and a process for etching the seed layer are performed while the substrate is immersed in a processing bath containing a predetermined processing liquid. The processing bath includes one capable of vertically housing a substrate (see International Publication No. WO 01/68952).

A wet-type substrate processing apparatus that performs processing such as cleaning processing and etching processing for a substrate such as a semiconductor wafer is roughly classified into a batch type apparatus and a sheet-fed type apparatus. The batch type apparatus holds a plurality of substrates in one carrier and immerses the substrates in a processing bath at once, and the sheet-fed type apparatus holds respective one substrates in substrate holding units and processes the substrates one at a time. Further, a substrate processing system in the sheet-fed type apparatus is classified into a system for conveying a substrate to processing baths with a robot and holding the substrate in a substrate holding unit included in each of the processing baths and a system for holding a substrate in a substrate holding unit called a substrate holder, conveying the substrate, together with the substrate holder, to the processing bath, and performing immersion processing. Examples of the wet-type substrate processing apparatus using a system for conveying a substrate holder that holds a substrate include an etching processing apparatus and a plating apparatus including a substrate attaching/detaching unit that automatically performs work for attaching and detaching the substrate to and from the substrate holder.

In a state where the wet-type substrate processing apparatus waits, the substrate holder is suspended in a vertical posture, and is stored in a stocker. On the other hand, when the wet-type substrate processing apparatus starts to operate, a substrate holder conveying device takes out the substrate holder from the stocker, and places the substrate holder on the substrate attaching/detaching unit. In the substrate attaching/detaching unit, a conveyance robot transfers the substrate to the substrate holder. The substrate holder conveying device carries the substrate holder, which holds the substrate, to a pre-wetting bath, for example, and first processing is performed for the substrate. At this time, in the conventional wet-type substrate processing apparatus, the stocker and the substrate attaching/detaching unit are separately arranged (see International Publication No. WO 01/68952).

However, the invention related to the above-mentioned conventional technique has the following issues. That is, in a processing bath that processes a substrate with the substrate vertically housed, the substrate is conveyed above the processing bath with a normal to its substrate surface facing in a horizontal direction and facing in a conveyance direction. When the substrate is thus conveyed, if another substrate is taken into and out of the processing bath, the other substrate, which is taken into and out of the processing bath, prevents the substrate from being conveyed. Thus, the substrate processing apparatus needs to wait for the conveyance of the substrate while the other substrate is taken into and out of the processing bath. Therefore, the throughput of the entire substrate processing apparatus decreases.

A stocker accommodates a large number of substrate holders, and occupies a wide place within a wet-type substrate processing apparatus. Thus, the wet-type substrate processing apparatus increases in size as a whole. After the substrate holder, which holds a substrate, is conveyed from a substrate attaching/detaching unit, the substrate attaching/detaching unit waits without doing anything until the subsequent substrate holder is conveyed from the stocker. That is, the speed at which the substrate is put into a processing unit in the wet-type substrate processing apparatus is reduced.

### SUMMARY OF INVENTION

The present invention has been made to solve at least one of the above-mentioned issues, and has as its one object to provide a substrate attaching/detaching unit capable of accommodating a large number of substrate holders in a wet-type substrate processing apparatus without increasing the footprint of the wet-type substrate processing apparatus and capable of quickly transferring the substrate holder.

The present invention has as its other object to make it difficult for conveyance of a substrate to be obstructed by another substrate that is taken into and out of a processing bath.

According to an aspect of the present invention, there is provided a substrate attaching/detaching unit. The substrate attaching/detaching unit includes a stocker accommodating a plurality of substrate holders and adapted so that the substrate holders are aligned in a vertical direction with one another in a horizontal posture, a first substrate holder conveying mechanism that takes the substrate holder into and out of the stocker, an elevating mechanism that raises and lowers the first substrate holder conveying mechanism in the vertical direction, a second substrate holder conveying mechanism that transfers the substrate holder to and from the first substrate holder conveying mechanism, and a substrate attaching/detaching mechanism that attaches and detaches the substrate to and from the substrate holder held in the second substrate holder conveying mechanism.

According to this aspect, the stocker is arranged below the second substrate holder conveying mechanism and the substrate attaching/detaching mechanism. Thus, a large number of substrate holders can be accommodated without increasing the footprint, as viewed from above, of the wet-type substrate processing apparatus. Even when the second substrate holder conveying mechanism or the substrate attaching/detaching mechanism grip the substrate holder, the first substrate holder conveying mechanism can wait while gripping the subsequent substrate holder. Thus, a period of time required for the second substrate holder conveying mechanism or the substrate attaching/detaching mechanism to wait can be shortened.

According to another aspect of the present invention, there is provided a substrate processing apparatus. The substrate processing apparatus includes a conveying machine including a holding unit that holds a substrate and a conveying unit that conveys the substrate held by the holding unit, and a processing bath that houses the substrate with a normal to its substrate surface facing in a conveyance direction, to process the substrate, in which the holding unit is adapted to hold the substrate with the normal to the substrate surface facing in a horizontal direction and facing in a direction perpendicular to the conveyance direction, and the conveyance unit is adapted to convey the substrate with the normal to the substrate surface facing in the horizontal direction and facing in the direction perpendicular to the conveyance direction.

According to this aspect, the conveyance of the substrate can be inhibited from being obstructed by another substrate that is taken into and out of the processing bath.

According to a still another aspect of the present invention, there is provided a substrate conveying method. The substrate conveying method includes the steps of conveying the substrate with a normal to its substrate surface facing in a horizontal direction and facing in a direction perpendicular to a conveyance direction, swirling the substrate so that the normal to the substrate surface faces in the conveyance direction, and housing the substrate in a processing bath with the normal to the substrate surface facing in the conveyance direction.

According to a further aspect of the present invention, there is provided a substrate processing apparatus. The substrate processing apparatus includes a substrate holder that holds a substrate, a conveying machine including a holding unit that holds the substrate holder and a conveying unit that conveys the substrate holder held in the holding unit, and a processing bath that houses the substrate and the substrate holder with a normal to its substrate surface facing in a conveyance direction of the conveying machine, to process the substrate, in which the holding unit is adapted to hold the substrate beside the processing bath when the conveying unit conveys the substrate.

### BRIEF DESCRIPTION OF DRAWINGS

FIG. 1 is a schematic plan view of a wet-type substrate processing apparatus including a stocker according to an embodiment of the present invention;

FIG. 2 is a perspective view of a substrate conveying device and a substrate attaching/detaching unit that are installed in the wet-type substrate processing apparatus illustrated in FIG. 1;

FIG. 3 is a front view of the substrate attaching/detaching unit installed in the wet-type substrate processing apparatus illustrated in FIG. 1;

FIG. 4 is a perspective view of the substrate attaching/detaching unit installed in the wet-type substrate processing apparatus illustrated in FIG. 1;

FIGS. 5A and 5B illustrate a substrate holder, where FIG. 5A illustrates a plan view of a substrate holder, and FIG. 5B illustrates a perspective view of a substrate holder;

FIG. 6 is an enlarged perspective view of a holder portion in the substrate holder illustrated in FIG. 5;

FIGS. 7A, 7B and 7C illustrate a first substrate holder conveying mechanism illustrated in FIG. 3, where FIG. 7A is a perspective view viewed from its back surface, FIG. 7B is a perspective view viewed from its front surface, and FIG. 7C is a side view;

FIGS. 8A, 8B and 8C illustrate a substrate attaching/detaching mechanism illustrated in FIG. 3, where FIG. 8A illustrates a perspective view, FIG. 8B illustrates a perspective view of a state where a substrate is gripped, and FIG. 8C is a side view;

FIGS. 9A and 9B illustrate a second substrate holder conveying mechanism illustrated in FIG. 3, wherein FIG. 9A is a perspective view, and FIG. 9B is a side view;

FIG. 10 is a perspective view illustrating a stocker illustrated in FIG. 3 and particularly illustrating a state where the substrate holder has moved upward;

FIGS. 11A-1-11D-2 illustrate an operation of the stocker, where FIGS. 11A-1, 11B-1, 11C-1, and 11D-1 are perspective views, and FIGS. 11A-2, 11B-2, 11C-2, and 11D-2 are plan views obtained by respectively omitting part of FIGS. 11A-1, 11B-1, 11C-1, and 11D-1;

FIGS. 12A-1-12D-2 illustrate an operation of the stocker subsequently to FIGS. 11A-1-11D-2, where FIGS. 12A-1, 12B-1, 12C-1, and 12D-1 are perspective views, and FIGS. 12A-2, 12B-2, 12C-2, and 12D-2 are plan views and perspective views obtained by respectively omitting part of FIGS. 12A-1, 12B-1, 12C-1, and 12D-1;

FIGS. 13A and 13B illustrate a rotary actuator provided in the second substrate holder conveying mechanism, where FIG. 13A illustrates a state where a substrate has not pressed, and FIG. 13B illustrates a state where the substrate is pressed;

FIG. 14 is a side sectional view of a substrate attaching/detaching unit according to the second embodiment including a stocker that holds a substrate holder in a vertical posture;

FIG. 15 is a perspective view illustrating a lifter;

FIG. 16 is a perspective view of a substrate conveying device;

FIG. 17 is a perspective view of a substrate conveying device that holds a substrate W in a horizontal direction;

FIG. 18 is a perspective view of a substrate conveying device that holds a substrate W so that a normal to a substrate surface of the substrate W faces in a horizontal direction and faces in a direction perpendicular to a conveyance direction;

FIG. 19 is a front view of the substrate conveying device;

FIG. 20 is a partially enlarged view of a holding mechanism;

FIG. 21 is a perspective view of the substrate conveying device including a first gas jetting unit;

FIG. 22 is a front view of the substrate conveying device including a first gas jetting unit;

FIG. 23 is a perspective view of the substrate conveying device including a second gas jetting unit;

FIG. 24 is a perspective view of a substrate conveying device in a substrate processing apparatus according to a fourth embodiment;

FIG. 25 is a perspective view of a substrate conveying device that holds a substrate in a conveyance direction;

FIG. 26 is a front view of a substrate conveying device; and

FIG. 27 is a perspective view of a substrate conveying device including a second gas jetting unit.

### DESCRIPTION OF EMBODIMENTS

According to a first aspect of the present invention, there is provided a substrate attaching/detaching unit. The substrate attaching/detaching unit includes a stocker accommodating a plurality of substrate holders and adapted so that the substrate holders are aligned in a vertical direction with one another in a horizontal posture, a first substrate holder conveying mechanism that takes the substrate holder into and out of the stocker, an elevating mechanism that raises and lowers the first substrate holder conveying mechanism in the vertical direction, a second substrate holder conveying mechanism that transfers the substrate holder to and from the first substrate holder conveying mechanism, and a substrate attaching/detaching mechanism that attaches and detaches the substrate to and from the substrate holder held in the second substrate holder conveying mechanism.

According to the first aspect, the stocker is arranged below the second substrate holder conveying mechanism and the substrate attaching/detaching mechanism. Thus, the large number of substrate holders can be accommodated without increasing the footprint, as viewed from above, of the wet-type substrate processing apparatus. Even when the second substrate holder conveying mechanism or the substrate attaching/detaching mechanism grips the substrate holder, the first substrate holder conveying mechanism can wait while gripping the subsequent substrate holder. Thus, a period of time required for the second substrate holder conveying mechanism or the substrate attaching/detaching mechanism to wait can be shortened.

According to a second aspect of the present invention, the substrate attaching/detaching unit according to the first aspect includes a plurality of substrate holder accommodating portions that respectively accommodate the plurality of substrate holders, in which each of the substrate holder accommodating portions includes holder receiving portions at at least three points, the respective heights of which are equal to one another.

According to a third aspect of the present invention, in the substrate attaching/detaching unit according to the first or second aspect, the substrate holder includes a linear first portion and two second portions each extending in a direction substantially perpendicular to the first portion and having a leading end bent in a hook shape, the substrate being held between the two second portions, and the holder receiving portion receives both ends of the first portion and the leading ends of the second portions.

According to a fourth aspect of the present invention, in the substrate attaching/detaching unit according to any one of the first to third aspects, the first substrate holder conveying mechanism holds the substrate holder at three points from inside the first portion and the second portions, and is movable in the vertical direction by the elevating mechanism.

According to a fifth aspect of the present invention, in the substrate attaching/detaching unit according to any one of the first to fourth aspects, the substrate attaching/detaching mechanism includes a base member, a linear guide that movably supports the base member in a linear direction, an actuator that moves the base member along the linear guide, and a substrate guide that is arranged on the base member to hold the substrate in a horizontal posture.

According to a sixth aspect of the present invention, in the substrate attaching/detaching unit according to any one of the third to fifth aspects, the second substrate holder conveying mechanism includes a clamper that holds the two second portions from outside, and a rotary actuator for pressing the substrate toward the leading ends of the second portions.

According to a seventh aspect of the present invention, in the substrate attaching/detaching unit according to any one of the first to sixth aspects, the second substrate holder conveying mechanism includes two sets of chucks that hold the substrate holders.

According to an eighth aspect of the present invention, in the substrate attaching/detaching unit according to any one of the first to seventh aspects, the elevating mechanism includes a linear guide extending in the vertical direction, a ball screw coupled to the first substrate holder conveying mechanism, a threaded shaft threadably mounted on the ball screw and extending in the vertical direction, and an electric motor that rotates the threaded shaft via a timing belt.

According to a ninth aspect of the present invention, in the substrate attaching/detaching unit according to any one of the first to eighth aspects, the stocker is provided below the substrate attaching/detaching mechanism and the second substrate holder conveying mechanism.

According to a tenth aspect of the present invention, there is provided a wet-type substrate processing apparatus. The wet-type substrate processing apparatus includes a substrate holder that holds a substrate, a processing bath accommodating the substrate holder to perform processing, a conveying machine that conveys the substrate holder to the processing bath, and the substrate attaching/detaching unit in any one of the first to ninth aspects.

According to an eleventh aspect of the present invention, the wet-type substrate processing apparatus according to the tenth aspect further includes a second elevating mechanism that raises and lowers the second substrate holder conveying mechanism in the vertical direction, in which the second elevating mechanism is adapted to transfer the substrate holder that holds the substrate to the conveying machine.

According to a twelfth aspect of the present invention, in the wet-type substrate processing apparatus according to the tenth or eleventh aspect, the second substrate holder conveying mechanism includes two sets of chucks each holding the substrate holder.

According to a thirteenth aspect of the present invention, there is provided a substrate holder conveying method using the wet-type substrate processing apparatus according to the twelfth aspect. In the substrate holder conveying method, the second substrate holder conveying mechanism receives a first substrate holder that grips the substrate before the processing with one of the sets of chucks while receiving a second substrate holder that grips the substrate after the processing with the other set of chucks, and transfers the first substrate holder to the conveying machine while removing the substrate from the second substrate holder, and transfers the second substrate holder to the first substrate holder conveying mechanism.

According to a fourteenth aspect of the present invention, there is provided a substrate processing apparatus. The substrate processing apparatus includes a conveying machine including a holding unit that holds a substrate and a conveying unit that conveys the substrate held by the holding unit, and a processing bath that houses the substrate with a normal to its substrate surface facing in a conveyance direction, to process the substrate, in which the holding unit is adapted to hold the substrate with the normal to the substrate surface facing in a horizontal direction and facing in a direction perpendicular to the conveyance direction, and the conveying unit is adapted to convey the substrate with the normal to the substrate surface facing in the horizontal direction and facing in the direction perpendicular to the conveyance direction.

According to the fourteenth aspect, the conveyance of the substrate can be inhibited from being obstructed by another substrate that is taken into and out of the processing bath.

According to a fifteenth aspect, in the substrate processing apparatus according to the fourteenth aspect, when the conveying unit conveys the substrate with the normal to the substrate surface facing in the horizontal direction and facing in the direction perpendicular to the conveyance direction, the holding unit is adapted to hold the substrate beside the processing bath.

According to a sixteenth aspect of the present invention, the substrate processing apparatus according to the fifteenth aspect further includes a liquid receiving unit provided beside the processing bath, in which the holding unit is adapted to hold the substrate above the liquid receiving unit when the conveying unit conveys the substrate with the normal to the substrate surface facing in the horizontal direction and facing in the direction perpendicular to the conveyance direction.

According to a seventeenth aspect of the present invention, the substrate processing apparatus according to the fifteenth or sixteenth aspect further includes a first gas jetting unit forming an air curtain for atmospherically separating the substrate, which is held with the normal to the substrate surface facing in the horizontal direction and facing in the direction perpendicular to the conveyance direction, and the processing bath.

According to an eighteenth aspect of the present invention, the substrate processing apparatus according to any one of the fourteenth to seventeenth aspects further includes a second gas jetting unit for spraying gas in an in-plane direction on both sides of the substrate when the substrate is positioned above the processing bath.

According to a nineteenth aspect of the present invention, in the substrate processing apparatus according to any one of the fourteenth to eighteenth aspects, the conveying machine includes a first driving mechanism that swirls the holding unit around its axis in the horizontal direction and the direction perpendicular to the conveyance direction and a second driving mechanism that swirls the holding unit around its axis in the conveyance direction.

According to a twentieth aspect of the present invention, in the substrate processing apparatus according to any one of the fourteenth to eighteenth aspects, the conveying machine includes a third driving mechanism that swirls the holding unit around its axis in a vertical direction.

According to a twenty-first aspect of the present invention, there is provided a substrate conveying method. The substrate conveying method includes the steps of conveying the substrate with a normal to its substrate surface facing in a horizontal direction and facing in a direction perpendicular to a conveyance direction, swirling the substrate so that a normal to the substrate surface faces in the conveyance direction, and housing the substrate in a processing bath with the normal to the substrate facing in the conveyance direction.

According to a twenty-second aspect of the present invention, there is provided a substrate processing apparatus. The substrate processing apparatus includes a substrate holder that holds a substrate, a conveying machine including a holding unit that holds the substrate holder and a conveying unit that conveys the substrate holder held in the holding unit, and a processing bath that houses the substrate and the substrate holder with a normal to its substrate surface facing in a conveyance direction of the conveying machine, to process the substrate, in which the holding unit is adapted to hold the substrate beside the processing bath when the conveying unit conveys the substrate.

According to a twenty-third aspect of the present invention, the substrate processing apparatus according to the twenty-second aspect further includes a liquid receiving unit provided beside the processing bath, in which the holding unit is adapted to hold the substrate above the liquid receiving unit when the conveying unit conveys the substrate.

According to a twenty-fourth aspect of the present invention, the substrate processing apparatus according to the twenty-second or twenty-third aspect further includes a first gas jetting unit forming an air curtain for atmospherically separating the substrate and the processing bath from each other when the conveying unit conveys the substrate.

According to a twenty-fifth aspect of the present invention, the substrate processing apparatus according to any one of the twenty-second to twenty-fourth aspects further includes a second gas jetting unit that sprays gas in an in-plane direction on both sides of the substrate when the substrate is positioned above the processing bath.

According to a twenty-sixth aspect of the present invention, in the substrate processing apparatus according to any one of the twenty-second to twenty-fifth aspects, the holding unit is adapted to hold the substrate with the normal to the substrate surface facing in the direction perpendicular to the conveyance direction, and the conveying unit is adapted to convey the substrate with the normal to the substrate surface facing in the direction perpendicular to the conveyance direction.

According to a twenty-seventh aspect of the present invention, in the substrate processing apparatus according to the twenty-sixth aspect, the holding unit is adapted to hold the substrate with the normal to the substrate surface facing in a horizontal direction.

According to the twenty-eighth aspect of the present invention, in the substrate processing apparatus according to the twenty-sixth or twenty-seventh aspect, the conveying machine includes a first driving mechanism that swirls the holding unit around its axis in the horizontal direction and the direction perpendicular to the conveyance direction and a second driving mechanism that swirls the holding unit around its axis in the conveyance direction.

According to the twenty-ninth aspect of the present invention, in the substrate processing apparatus according to any one of the twenty-sixth or twenty-seventh aspect, the conveying machine includes a third driving mechanism that swirls the holding unit around its axis in a vertical direction.

Embodiments of the present invention will be described below with reference to the accompanying drawings. In the drawings, described below, identical or corresponding components are assigned the same reference numerals, and hence an overlapped description is omitted. It should be noted that an invention, which is any combination of individual components, described below, is included in a technical idea covered by the invention.

### First Embodiment

[Overall Outline]

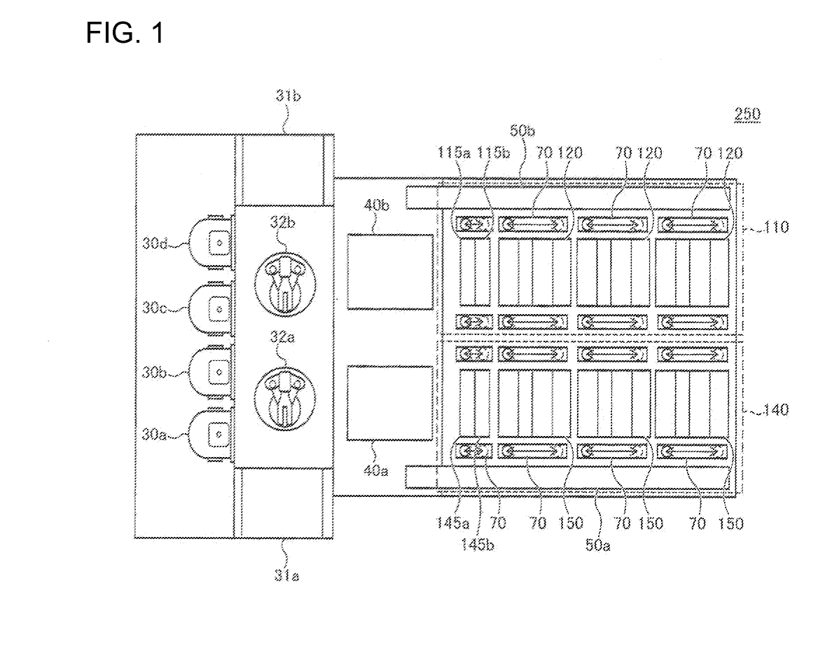

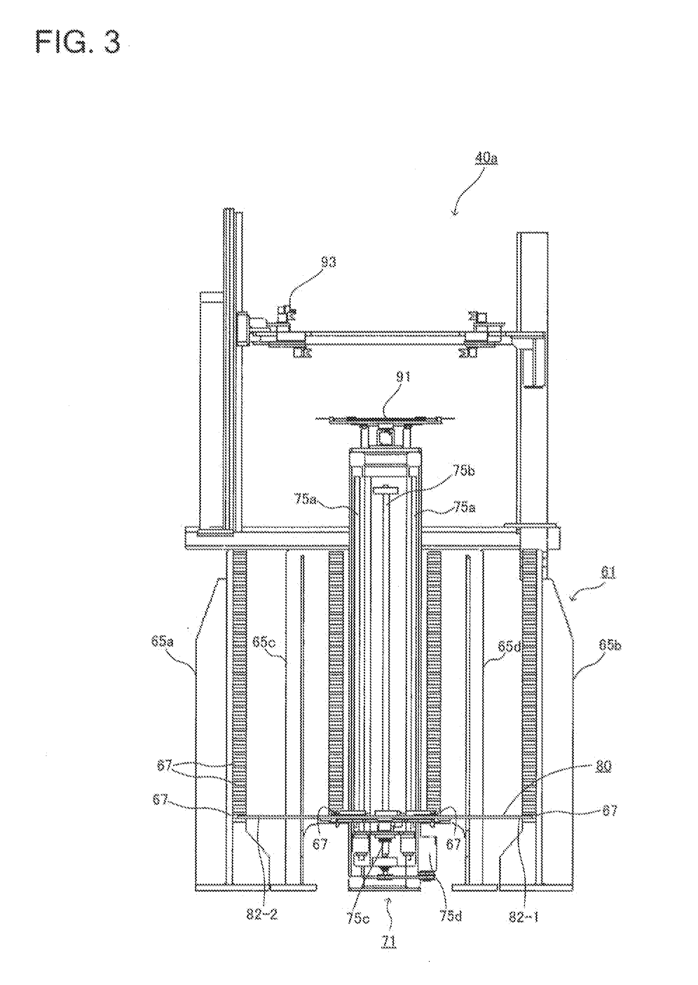

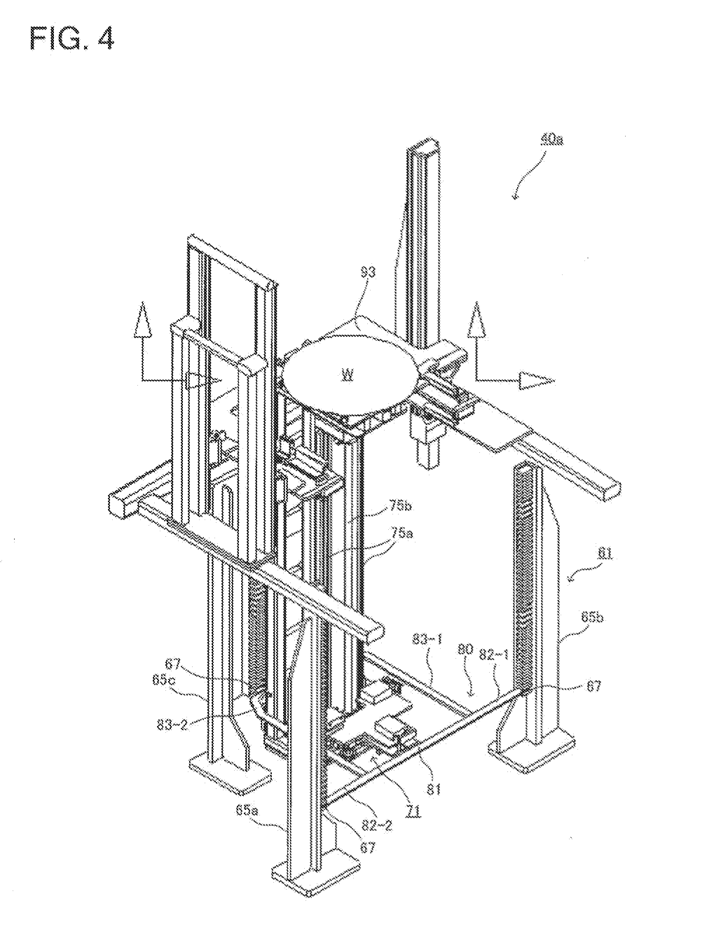

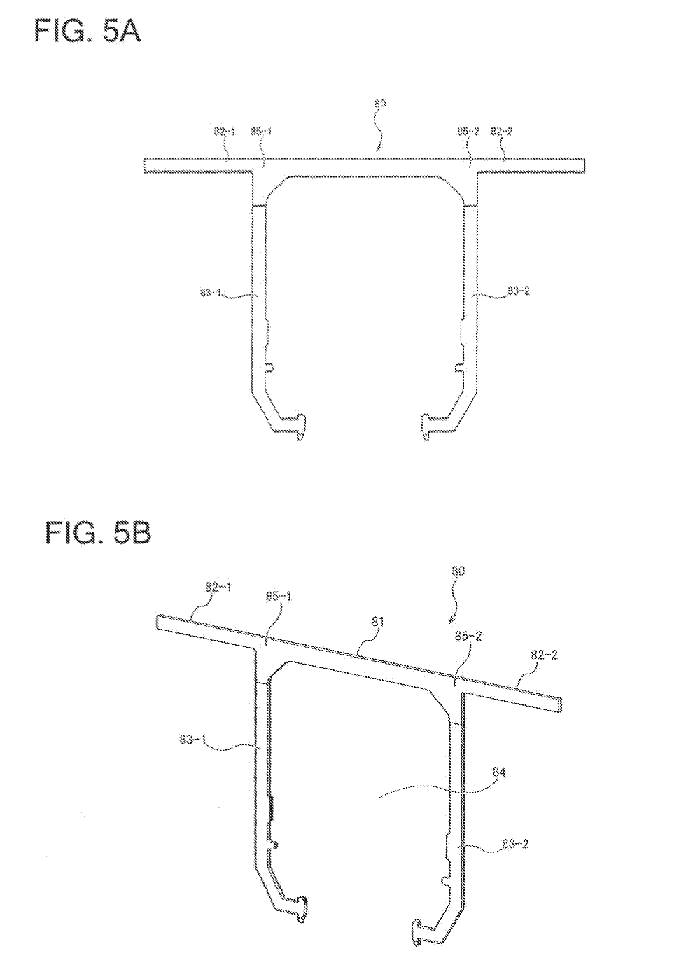

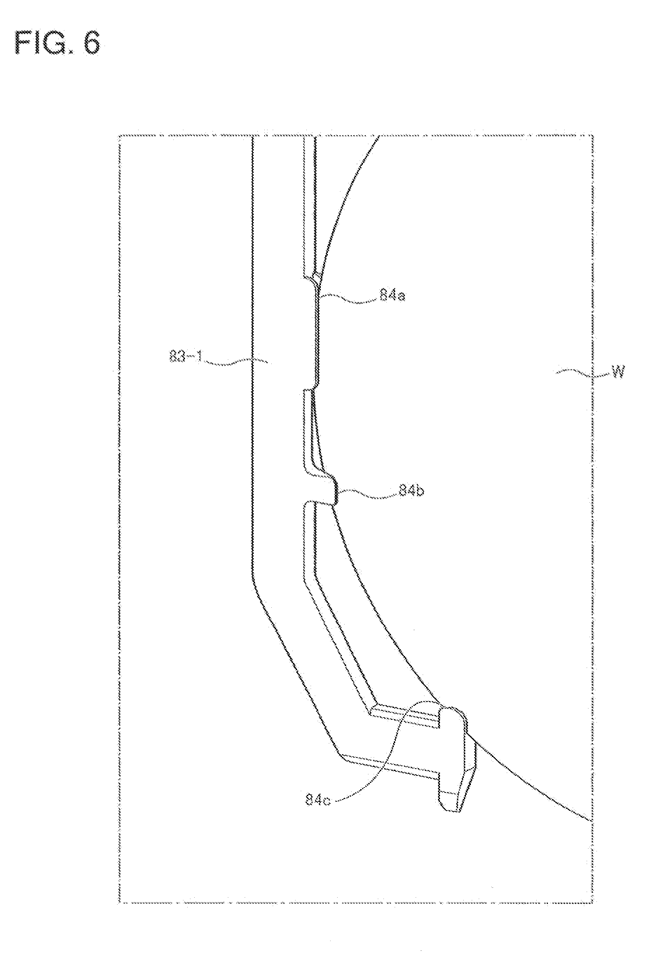

FIG. 1 is a schematic plan view illustrating a wet-type substrate processing apparatus 250 according to the present embodiment. FIGS. 3 and 4 respectively illustrate substrate attaching/detaching units 40a and 40b installed in the wet-type substrate processing apparatus 250, FIGS. 5A and 5B illustrate a substrate holder 80, and FIG. 6 is an enlarged view of a holder portion 83-1 illustrated in FIG. 5.

As illustrated in FIG. 1, four cassettes 30a, 30b, 30c, and 30d that house a substrate such as a semiconductor wafer, two substrate drying machines 31a and 31b that dry the substrate after processing, substrate attaching/detaching units 40a and 40b that attach and detach the substrate to and from a substrate holder, and two robot hands 32a and 32b that convey the substrate between the units are arranged in the wet-type substrate processing apparatus 250. Four substrate drying machines may be arranged in the wet-type substrate processing apparatus 250. That is, the two substrate drying machines are vertically arranged at each of positions where the substrate drying machines 31a and 31b are arranged.

A substrate to be processed by a resist stripping unit 140, described below, is taken out of the cassette 30a or 30b with a robot hand 32a, and is conveyed to the substrate attaching/detaching unit 40a. The resist stripping unit 140 then strips a resist from the substrate mounted on the substrate holder in the substrate attaching/detaching unit 40a. The substrate, from which the resist has been stripped by the resist stripping unit 140, is taken out of the substrate holder in the substrate attaching/detaching unit 40a. The substrate, which has been taken out of the substrate holder, is conveyed from the substrate attaching/detaching unit 40a to the substrate drying machine 31a with the robot hand 32a. The substrate drying machine 31a cleans and dries the substrate using Iso-Propyl Alcohol (IPA) and De-Ionized Water (DIW). The dried substrate is returned to the cassette 30a or 30b with the robot hand 32a.

Similarly, a substrate to be etched by an etching unit 110, described below, is taken out of the cassette 30c or 30d with the robot hand 32b, and is conveyed to the substrate attaching/detaching unit 40b. The etching unit 110 then etches the substrate that has been mounted on the substrate holder in the substrate attaching/detaching unit 40b. The substrate, which has been etched by the etching unit 110, is taken out of the substrate holder in the substrate attaching/detaching unit 40b. The substrate, which has been taken out of the substrate holder, is conveyed to the substrate drying machine 31b from the substrate attaching/detaching unit 40b with the robot hand 32b. The substrate drying machine 31b cleans and dries the substrate using IPA and DIW. The dried substrate is returned to the cassette 30c or 30d with the robot hand 32b.

The wet-type substrate processing apparatus 250 includes the resist stripping unit 140 that strips the resist formed on the substrate. The resist striping unit 140 includes two pre-wetting baths 145a and 145b for improving a hydrophilic property on a surface of the substrate, and three resist stripping modules 150 for stripping the resist formed on the substrate. Each of the resist stripping modules 150 includes a plurality of baths. Along both sides of the pre-wetting baths 145a and 145b, there are provided lifters 70 capable of horizontal movement, which house or take out the substrate holder in and from each of the pre-wetting baths 145a and 145b. Similarly, along both sides of the resist stripping module 150, there are provided lifters 70 capable of horizontal movement, which house or take out the substrate holder in or from each of the plurality of baths constituting the resist stripping module 150. The resist stripping unit 140 includes a substrate attaching/detaching unit 40a, and a substrate conveying device 50a (corresponding to an example of a conveying machine) that conveys the substrate between the lifters 70 provided for the pre-wetting baths 145a and 145b and the lifters 70 provided for the resist stripping module 150.

When the resist on the substrate is stripped, the substrate holder that holds the substrate is transferred to the substrate conveying device 50a from the substrate attaching/detaching unit 40a, and is transfers to the lifters 70 provided for the pre-wetting baths 145a and 145b by the substrate conveying device 50a. The lifters 70 house the transferred substrate holder in empty one of the pre-wetting baths 145a and 145b. DIW and IPA are sprayed to the substrate in the pre-wetting bath 145a or 145b. After the substrate is processed in the pre-wetting bath 145a or 145b, the substrate holder is taken out of the pre-wetting bath 145a or 145b by the lifters 70, and is transferred to the substrate conveying device 50a. The substrate holder is transferred to the lifters 70 provided for any one of the resist stripping modules 150 by the substrate conveying device 50a, and is housed in a processing bath in the resist stripping modules 150 by the lifters 70. After the substrate is processed in the resist stripping module 150, the substrate holder is taken out of the processing bath by the lifters 70 provided for the resist stripping module 150, and is transferred to the substrate conveying device 50a. The substrate conveying device 50a returns the substrate holder to the substrate attaching/detaching unit 40a.

The wet-type substrate processing apparatus 250 includes the etching unit 110 that etches a seed layer formed on a substrate. The etching unit 110 includes two pre-wetting baths 115a and 115b for improving a hydrophilic property on a surface of the substrate and three etching modules 120 for etching the seed layer formed on the substrate. Each of the etching modules 120 includes a plurality of baths. Along both sides of the pre-wetting baths 115a and 115b, there are provided lifters 70 that house or take out the substrate holder in or from each of the pre-wetting baths. Similarly, along both sides of the etching module 120, there are provided lifters 70 that house or take out the substrate holder in or from the plurality of baths constituting the etching module 120. The etching unit 110 includes the substrate attaching/detaching unit 40b, and a substrate conveying device 50b (corresponding to an example of a conveying machine) that conveys the substrate between the lifters 70 provided for the pre-wetting baths 115a and 115b and the lifters 70 provided for the etching module 120.

When the seed layer on the substrate is etched, the substrate holder, which holds the substrate, is transferred to the substrate conveying device 50b from the substrate attaching/detaching unit 40b, and is transferred to the lifters 70 provided for the pre-wetting baths 115a and 115b by the substrate conveying device 50b. The lifters 70 house the transferred substrate holder in empty one of the pre-wetting baths 115a and 115b. DIW or IPA is sprayed to the substrate in the pre-wetting bath 115a or 115b. After the substrate is processed in the pre-wetting bath 115a or 115b, the substrate holder is taken out of the pre-wetting bath 115a or 115b by the lifters 70, and is transferred to the substrate conveying device 50b. The substrate holder is transferred to the lifters 70 provided for any one of the etching modules 120 by the substrate conveying device 50b, and is housed in a processing bath in the etching module 120 by the lifters 70. After the substrate is processed in the etching module 120, the substrate holder is taken out of the processing bath by the lifters 70 provided for the etching module 120, and is transferred to the substrate conveying device 50b. The substrate holder is returned to the substrate attaching/detaching unit 40b by the substrate conveying device 50b.

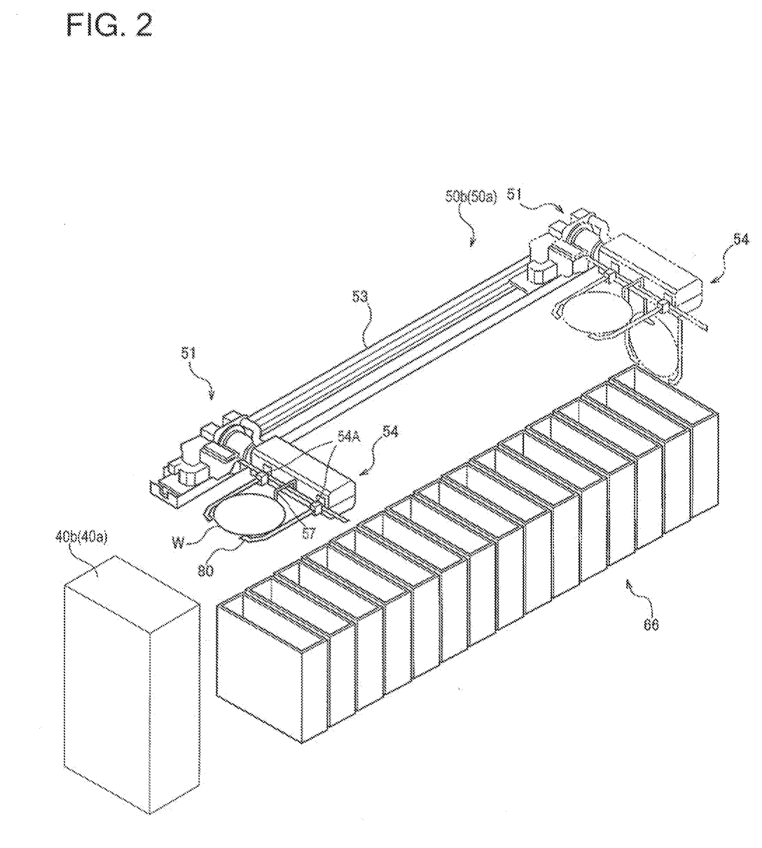

FIG. 2 illustrates the substrate conveying device 50b and a processing bath 66. The substrate conveying device 50a has a similar configuration, and hence description thereof is not repeated. The processing bath 66 is a simplified illustration of the pre-wetting bath and the resist stripping unit 140. The substrate conveying device 50b includes a holding mechanism 54 (corresponding to an example of a holding unit) for gripping a substrate holder 80, and a conveying mechanism 51 (corresponding to an example of a conveying unit) for conveying the substrate holder 80 gripped in the holding mechanism 54.

The holding mechanism 54 includes a chuck 54A vertically opened or closed, and can grip the substrate holder 80. Further, the holding mechanism 54 includes a substrate presser 57 to prevent a substrate W from coming off the substrate holder 80. When the substrate conveying device 50b receives the substrate holder 80, which holds the substrate W, in the substrate attaching/detaching unit 40b, the substrate holder 80 is gripped with an in-plane direction of the substrate W being a horizontal direction. The holding mechanism 54, which grips the substrate holder 80, can travel along a guide rail 53 from one end to the other end of the guide rail 53 by the conveying mechanism 51. The conveying mechanism 51 conveys the substrate holder 80 so that the substrate holder 80 passes above the processing bath 66 with the in-plane direction of the substrate W being the horizontal direction.

As illustrated in FIG. 1, the wet-type substrate processing apparatus 250 is adapted so that the cassettes 30c and 30d, the substrate drying machine 31b, the robot hand 32b, the substrate attaching/detaching unit 40b, and the etching unit 110 are in a substantially symmetric positional relationship with the cassettes 30a and 30b, the substrate drying machine 31a, the robot hand 32a, the substrate attaching/detaching unit 40a, and the resist striping unit 140. The present invention is applicable to a wet-type substrate processing apparatus that performs processing using a substrate holder that holds one substrate, for example, an electrolytic plating apparatus and a non-electrolytic plating apparatus.

[Substrate Attaching/Detaching Unit]

The substrate attaching/detaching units 40a and 40b as one feature point of the present embodiment will be specifically described below. Respective functions of the two substrate attaching/detaching units 40a and 40b are basically the same, and hence only the substrate attaching/detaching unit 40a will be described. FIG. 3 is a front view of the substrate attaching/detaching unit 40a, and FIG. 4 is a perspective view of the substrate attaching/detaching unit 40a. The substrate attaching/detaching unit 40a holds a plurality of substrate holders 80 (only one substrate holder 80 is accommodated in FIGS. 3 and 4), and includes a stocker 61 that receives the substrate holder 80 in a horizontal posture while being adapted so that a plurality of substrate holders 80 are aligned in a vertical direction.

The stocker 61 includes four columnar members 65a, 65b, 65c, and 65d. A plurality of slit-shaped holder receiving portions 67, which open in the horizontal direction, are formed in each of the columnar members 65a, 65b, 65c, and 65d. For example, 41 holder receiving portions 67 are provided for each of the columnar members 65a, 65b, 65c, and 65d. In each of the columnar members 65a, 65b, 65c, and 65d, the respective heights of the corresponding four holder receiving portions 67 are equal to one another. The four holder receiving portions 67 form one holder accommodating portion. The holder accommodating portion accommodates one substrate holder 80.

[Substrate Holder]

FIGS. 5A and 5B illustrate the substrate holder 80 accommodated in the stocker 61 in the present embodiment. As illustrated in FIGS. 5A and 5B, the substrate holder 80 includes a base portion 81 serving as a plate-shaped member formed to be long narrow, two arm portions 82-1 and 82-2 (corresponding to one example of a first portion), and two holder portions 83-1 and 83-2 (corresponding to one example of a second portion) for holding a substrate. Points where the base portion 81 crosses the arm portions 82-1 and 82-2 and the holder portions 83-1 and 83-2 are respectively gripped portions 85-1 and 85-2 of the substrate holder 80. The gripped portions 85-1 and 85-2 are gripped by the substrate conveying device 50a (or 50b).

The arm portions 82-1 and 82-2 are plate-shaped members formed extending from both ends of the base portion 81. Each of the arm portions 82-1 and 82-2 is suspended on a sidewall of the processing bath when the substrate holder 80 is immersed in the processing bath, as described later, and is supported by the lifters 70. The holder portions 83-1 and 83-2 are plate-shaped members in a substantially L shape formed in a direction substantially perpendicular from both ends of the base portion 81 to a longitudinal direction of the base portion 81. The substrate holder 80 can accommodate and hold a substrate such as a semiconductor wafer in a space 84 between the holder portions 83-1 and 83-2.

FIG. 6 is an enlarged perspective view of the holder portion 83-1 illustrated in FIG. 5. FIG. 6 illustrates a state where the substrate holder 80 holds the substrate W. The holder portion 83-1 has a plurality of slits 84a, 84b, and 84c along a surface opposing the holder portion 83-2, i.e., a surface opposing the space 84 illustrated in FIG. 5. The holder portion 83-2 also has a plurality of slits, which are similar to those of the holder portion 83-1, along the surface opposing the holder portion 83-1, which is not illustrated. The substrate W is held in the substrate holder 80 when its outer periphery is inserted into the slits 84a, 84b, and 84c of the holder portion 83-1 and the slits of the holder portion 83-2. Thus, the substrate W can be inhibited from falling from the substrate holder 80.

Referring to FIGS. 3 and 4 again, the stocker 61 will be described. As illustrated in FIGS. 3 and 4, ends of the arm portions 82-1 and 82-2 and leading ends of the holder portions 83-1 and 83-2 are received in the holder receiving portion 67 with the substrate holder 80 accommodated in the stocker 61. The respective heights of the four holder receiving portions 67, which correspond to one another, are equal. Thus, the substrate holder 80 is held in a substantially horizontal posture at its four points. However, the substrate holder 80 can be kept horizontal if supported at at least three points. Thus, the holder accommodating portion may be a combination of three holder receiving portions 67.

[First Substrate Holder Conveying Mechanism]

In FIGS. 3 and 4, the first substrate holder conveying mechanism 71 is provided in the vicinity of the substrate holder 80. The first substrate holder conveying mechanism 71 is used for taking out the substrate holder 80 from the holder receiving portion 67 and inserting the substrate holder 80 into the holder receiving portion 67. The first substrate holder conveying mechanism 71 is attached to an elevating mechanism, and can rise and fall in the vertical direction. In FIG. 3, the elevating mechanism includes a linear guide 75a extending in a linear shape in the vertical direction, a threaded shaft 75b extending parallel to the linear guide 75a, a ball screw 75c threadably mounted on the threaded shaft 75b, and a drive motor 75d that rotates the threaded shaft 75c via a timing belt. The ball screw 75c is fixed to an elevating base, described below.

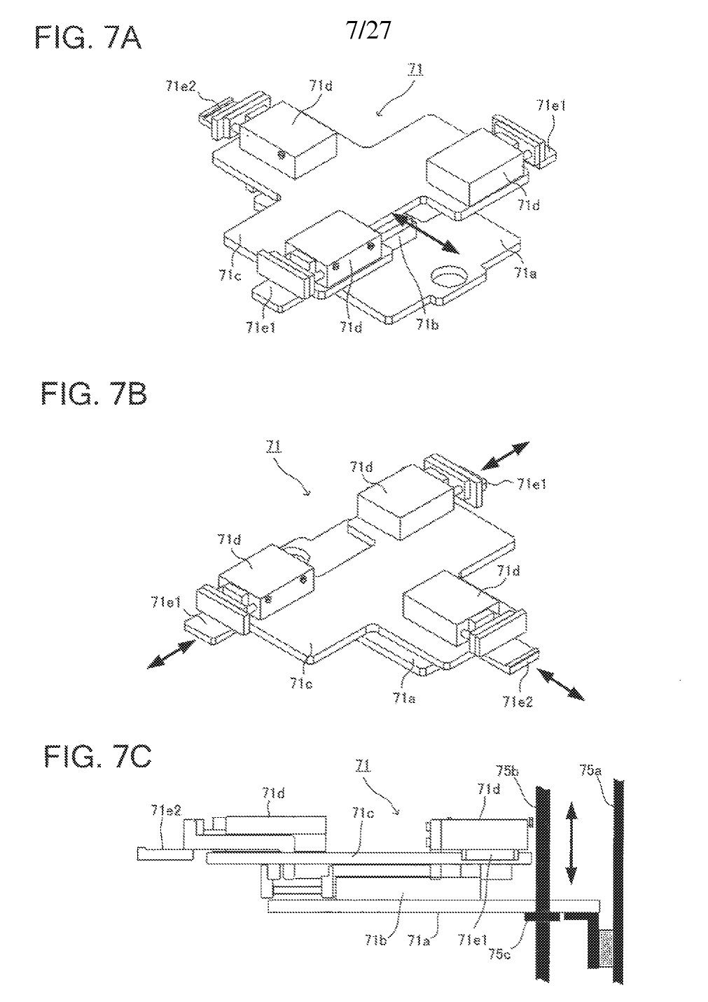

FIGS. 7A, 7B and 7C is a detailed view of the first substrate holder conveying mechanism 71. As illustrated in FIG. 7, the first substrate holder conveying mechanism 71 includes a plate-shaped elevating base 71a, a cylinder base driving cylinder 71b installed in the elevating base 71a, a cylinder base 71c that horizontally moves while being connected to the cylinder base driving cylinder 71b, and three holder clamp cylinders 71d arranged on the cylinder base 71c. The elevating base 71a is connected to an elevating mechanism including the linear guide 75a, the threaded shaft 75b, and the ball screw 75c, described above, and rises and falls in the vertical direction along the linear guide 75a by rotation of the threaded shaft 75b.

The cylinder base driving cylinder 71b arranged on the elevating base 71a moves the cylinder base 71c back and forth in one direction relative to the elevating base 71a. A specific direction is a direction in which the substrate holder 80 is inserted into the holder receiving portion 67 or pulled out of the holder receiving portion 67. The cylinder base driving cylinder 71b is an actuator that operates with air pressure or hydraulic pressure. However, the cylinder base driving cylinder 71b may be an actuator using an electric motor as a driving source.

The cylinder base 71c is a plate-shaped member in a substantially T shape, and is arranged above the elevating base 71a and the cylinder base driving cylinder 71b. Three holder clamp cylinder 71d are provided on the cylinder base 71c, and can move clamp members 71e1 and 71e2 in three directions. Two of the three holder clamp cylinders 71d are arranged to move the clamp member 71e1 in opposite directions on the same straight line, and the remaining one holder clamp cylinder 71d moves the clamp member 71e2 in a direction perpendicular to the same straight line. Each of the clamp members 71e1 and 71e2 has an L shape, and clamps the substrate holder 80 on its vertical surface while lifting the substrate holder 80 on its horizontal surface. A claw is formed on the horizontal surface of the clamp member 71e2 in the one holder clamp cylinder 71d. This is for preventing the base portion 81 in the substrate holder 80 from unintentionally coming off the horizontal surface of the clamp member 71e2 when the clamp member 71e2 clamps the base portion 81 in the substrate holder 80.

[Substrate Attaching/Detaching Mechanism]

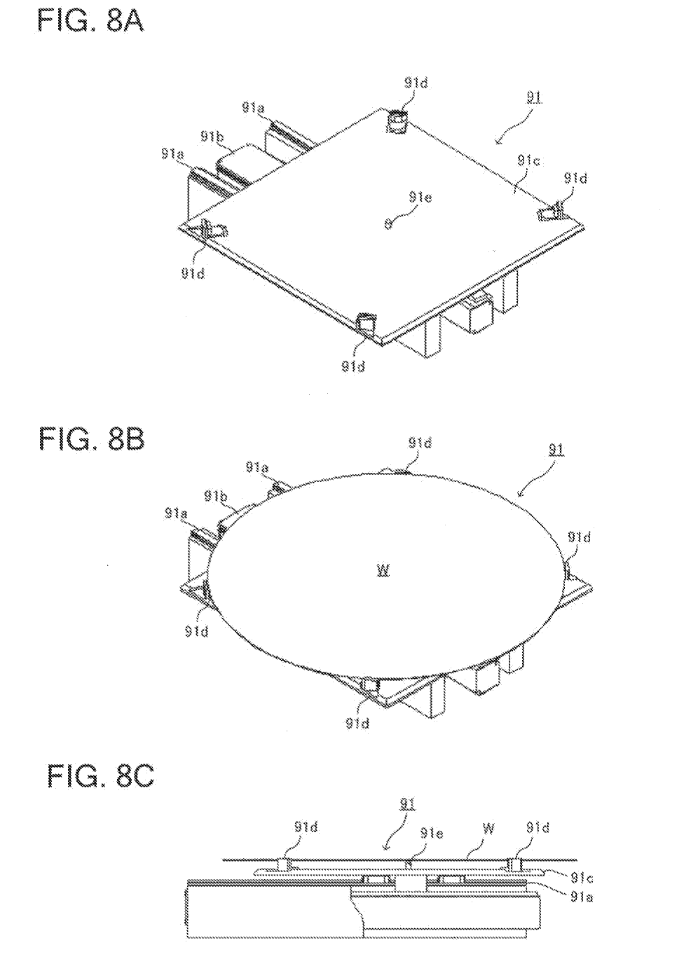

A substrate attaching/detaching mechanism 91 as illustrated in FIGS. 8A, 8B and 8C is provided at an upper end of the elevating mechanism. The substrate attaching/detaching mechanism 91 is used for mounting the substrate W on the substrate holder 80 and removing the substrate W from the substrate holder 80. The substrate attaching/detaching mechanism 91 includes two linear guides 91a extending parallel to the horizontal direction, an actuator 91b arranged between the linear guides 91a, and a substantially square base 91c linearly moving along the linear guides 91a with an operating force of the actuator 91b. Substantially L-shaped substrate guides 91d are installed at four corners of the base 91c. A center pin 91e is provided at the center of the base 91c. The center pin 91e has the same height as that when the substrate guides 91d grip the substrate W, and prevents the substrate W from being deflected when the substrate guides grip the substrate W.

When the substrate W is mounted on the substrate holder 80, the substrate holder 80, which is gripped by the clamp members 71e1 and 71e2 in the first substrate holder conveying mechanism 71 illustrated in FIG. 7, is arranged above the substrate attaching/detaching mechanism 91. The substrate holder 80 is transferred to a second substrate holder conveying mechanism 93, described below. On the other hand, the substrate attaching/detaching mechanism 91 places the substrate W, which has been received from the robot hand 32a or 32b, on the substrate guide 91d. In this state, the substrate attaching/detaching mechanism 91 positions the substrate W in the space 84 (see FIG. 5) in the substrate holder 80. Then, the substrate attaching/detaching mechanism 91 moves a base 91c in the horizontal direction, to insert the outer periphery of the substrate W into the slits 84a, 84b, and 84c illustrated in FIG. 6. The substrate holder 80, on which the substrate W is mounted, is conveyed to a processing unit in a subsequent stage (not illustrated).

On the other hand, when the processed substrate W is removed from the substrate holder 80, the substrate holder 80, which has been returned from the processing unit (not illustrated), is transferred to the second substrate holder conveying mechanism 93. Then, the substrate attaching/detaching mechanism 91 approaches the second substrate holder conveying mechanism 93, and positions the substrate guides 91d on the outer periphery of the substrate W. In this state, the substrate attaching/detaching mechanism 91 horizontally moves the base 91c in a direction in which the substrate W is removed from the substrate holder 80. When the substrate W is removed from the substrate holder 80, the substrate holder 80 is transferred to the first substrate holder conveying mechanism 71 from the second substrate holder conveying mechanism 93. Then, the first substrate holder conveying mechanism 71 returns the substrate holder 80 to the stocker 61.

In the above-mentioned embodiment, the clamp members 71e1 and 71e2 in the first substrate holder conveying mechanism 71 support the substrate holder 80 to press the substrate holder 80 outward from inside. Thus, the substrate attaching/detaching mechanism 91 cannot mount the substrate W on the substrate holder 80 while the first substrate holder conveying mechanism 71 supports the substrate holder 80. However, the first substrate holder conveying mechanism 71 can support the substrate holder 80 from below with a clearance between the substrate holder 80 and itself, and the substrate attaching/detaching mechanism 91 can transfer the substrate W from the clearance between the first substrate holder conveying mechanism 71 and the substrate holder 80. In this case, the substrate W need not be transferred to the substrate holder 80 with the substrate holder 80 supported by the second substrate holder conveying mechanism 93.

[Second Substrate Holder Conveying Mechanism]

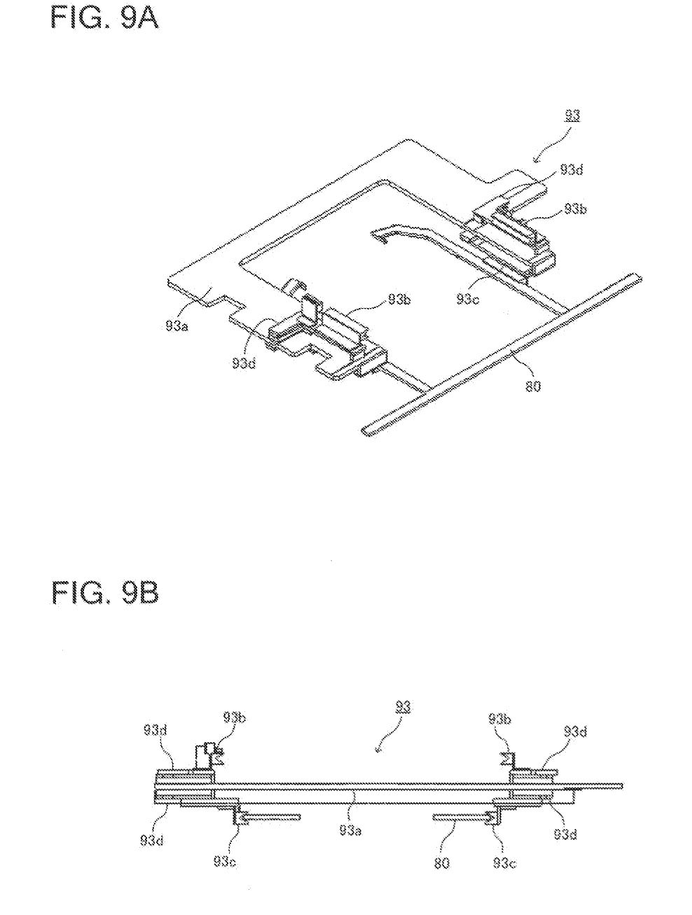

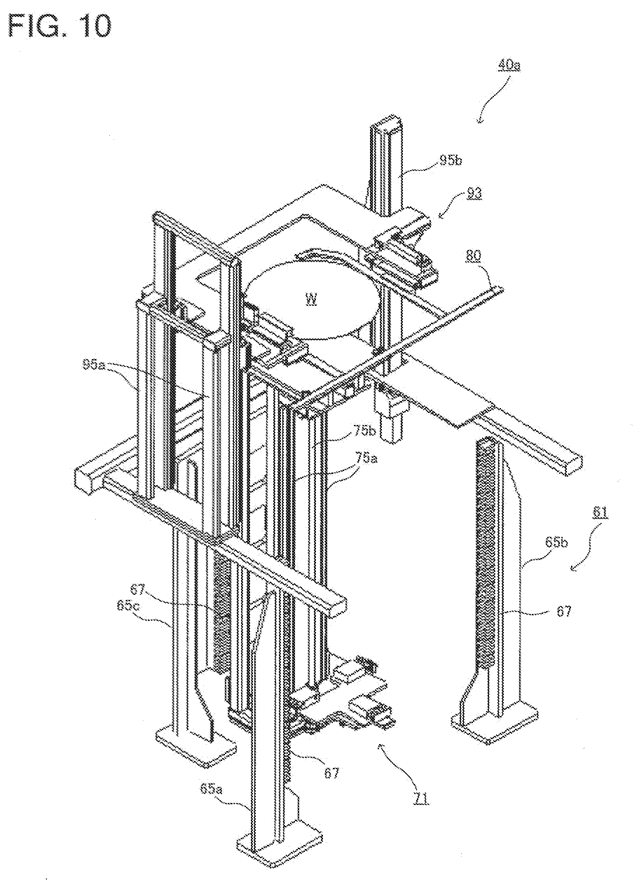

The second substrate holder conveying mechanism 93 will be described below with reference to FIGS. 9A and 9B. The second substrate holder conveying mechanism 93 is provided in the vicinity of the substrate attaching/detaching mechanism 91 (see FIG. 4 or 10). The second substrate holder conveying mechanism 93 receives the substrate holder 80 from the first substrate holder conveying mechanism 71, transfers the received substrate holder 80 to another processing unit (not illustrated), and receives a substrate holder 80 from the other processing unit. The second substrate holder conveying mechanism 93 includes a base 93a in a plate shape and in a substantially C shape, four clampers 93b and 93c arranged on both upper and lower surfaces at both ends of the base 93a, and clamper driving cylinders 93d for respectively moving the clampers 93b and 93c. Respective cross sections of the clampers 93b and 93c are in a substantially L shape, and the substrate holder 80 is gripped between the clampers 93b and 93c.

The two clampers 93b and 93c on the upper and lower sides operate to come closer to and separate from each other with an operating force of the clamper driving cylinder 93d, and can grip and release the substrate holder 80. FIG. 9B illustrates a state where the lower clampers 93c come closer to each other to grip the substrate holder 80. The upper and lower clamper driving cylinders 93d can be mutually and independently controlled. Therefore, the substrate holder 80 is held in only the upper clamper 93b, or the substrate holder 80 is held in only the lower clamper 93c. Alternatively, the substrate holder 80 can be held in the clampers 93b and 93c on both the upper and lower sides.

FIG. 10 illustrates a state where the substrate W is held in the substrate holder 80, and the second substrate holder conveying mechanism 93 grips the substrate holder 80. As illustrated in FIG. 10, the second substrate holder conveying mechanism 93 can rise and fall in the vertical direction by an elevating rail 95a and an actuator 95b extending in the vertical direction. FIG. 10 illustrates a state where the second substrate holder conveying mechanism 93 is at its uppermost position and the first substrate holder conveying mechanism 71 is at its lowermost position. As described above, a holder accommodating portion is provided below the substrate attaching/detaching mechanism 91 and the second substrate holder conveying mechanism 93. Thus, a multifunctional stocker can be implemented without increasing a footprint.

[Operation]

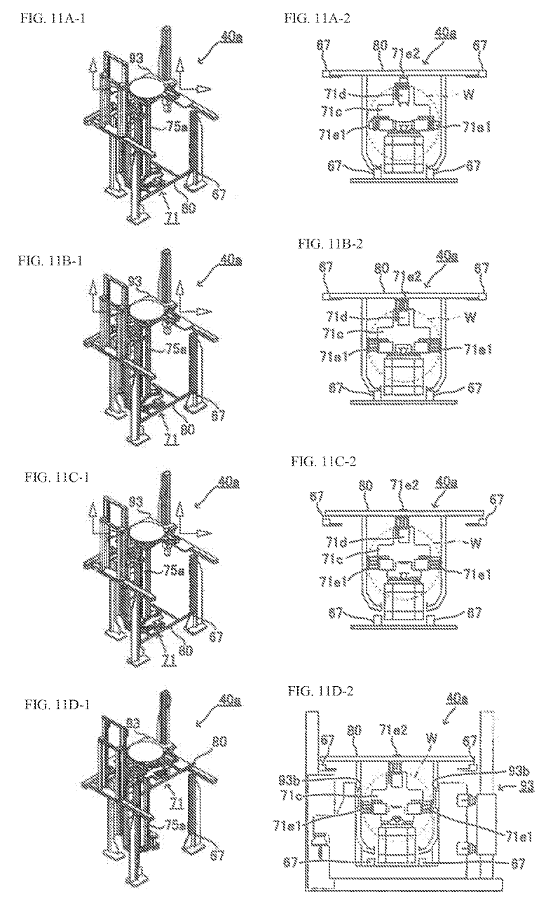

An operation of the substrate attaching/detaching unit 40a in the present exemplary embodiment will be described below with reference to FIGS. 11A1-11D-2 and 12A-1-12D-2. FIGS. 11A-1 and 11A-2 illustrate a state where the one substrate holder 80 is accommodated in a lowermost part of the holder receiving portion 67 in the stocker 61 and the first substrate holder conveying mechanism 71 is positioned below the substrate holder 80. The holder clamp cylinder 71d in the first substrate holder conveying mechanism 71 is retreated to a position at which the clamp members 71e1 and 71e2 do not abut on the substrate holder 80. As illustrated in FIGS. 11B-1 and 11B-2, the holder clamp cylinder 71d then pushes the clamp members 71e1 and 71e2, to make the clamp members 71e1 and 71e2 abut on the inner side of the substrate holder 80. Thus, the first substrate holder conveying mechanism 71 holds the substrate holder 80.

As illustrated in FIGS. 11C-1 and 11C-2, a cylinder base driving cylinder (not illustrated) operates, to move the cylinder base 71c. A direction in which the cylinder base 71c moves is a direction in which the substrate holder 80 separates from the holder receiving portion 67 (upward in FIG. 11C-2). Thus, the substrate holder 80 can move up and down. A movement distance is approximately 50 mm. As illustrated in FIGS. 11D-1 and 11D-2, the first substrate holder conveying mechanism 71 moves upward in the vertical direction along the linear guide 75a by the rotation of the threaded shaft 75b and the function of the ball screw 75c, and stops in the vicinity of the substrate attaching/detaching mechanism 91 (see FIG. 3) while the substrate holder 80 is gripped on both right and left sides by the clampers 93b and 93c in the second substrate holder conveying mechanism 93. That is, the substrate holder 80 remains gripped by both the first substrate holder conveying mechanism 71 and the second substrate holder conveying mechanism 93.

Then, as illustrated in FIGS. 12A-1 and 12A-2, the holder clamp cylinders 71d in the first substrate holder conveying mechanism 71 operate, to retreat the clamp members 71e1 and 71e2. Then, the first substrate holder conveying mechanism 71 slightly falls downward. Thus, the clamp members 71e1 and 71e2 separate from the substrate holder 80. Then, the substrate attaching/detaching mechanism 91 rises until the substrate W is level with the substrate holder 80. In the state, the substrate W horizontally moves toward the respective leading ends of the holder portions 83-1 and 83-2 in the substrate holder 80, as illustrated in FIGS. 12B-1 and 12B-2. The substrate W moves by the function of the actuator 91b in the substrate attaching/detaching mechanism 91 (see FIG. 8). The first substrate holder conveying mechanism 71 transfers the substrate holder 80 to the second substrate holder conveying mechanism 93, and then supports the subsequent substrate holder 80 accommodated in the holder receiving portion 67, to prepare for attachment/detachment of the subsequent substrate.

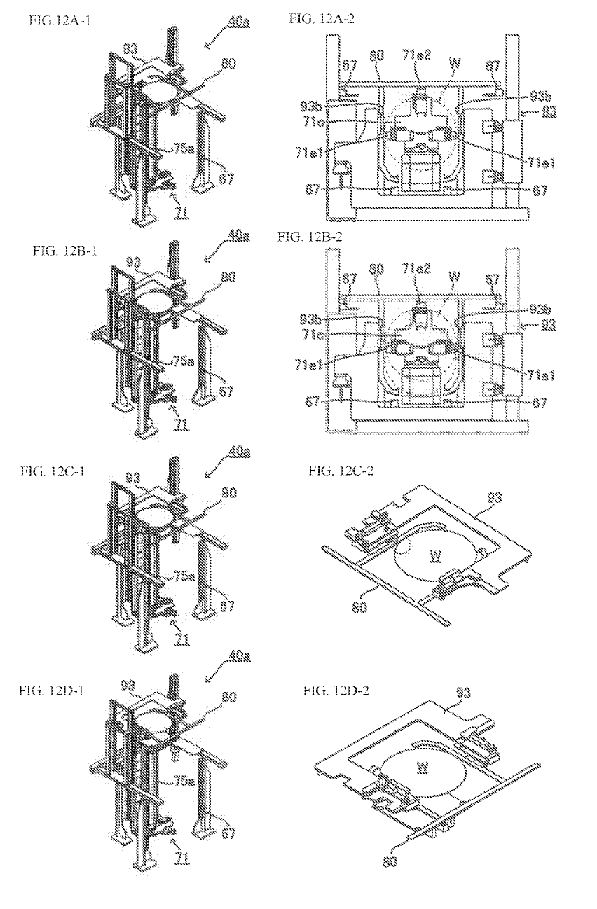

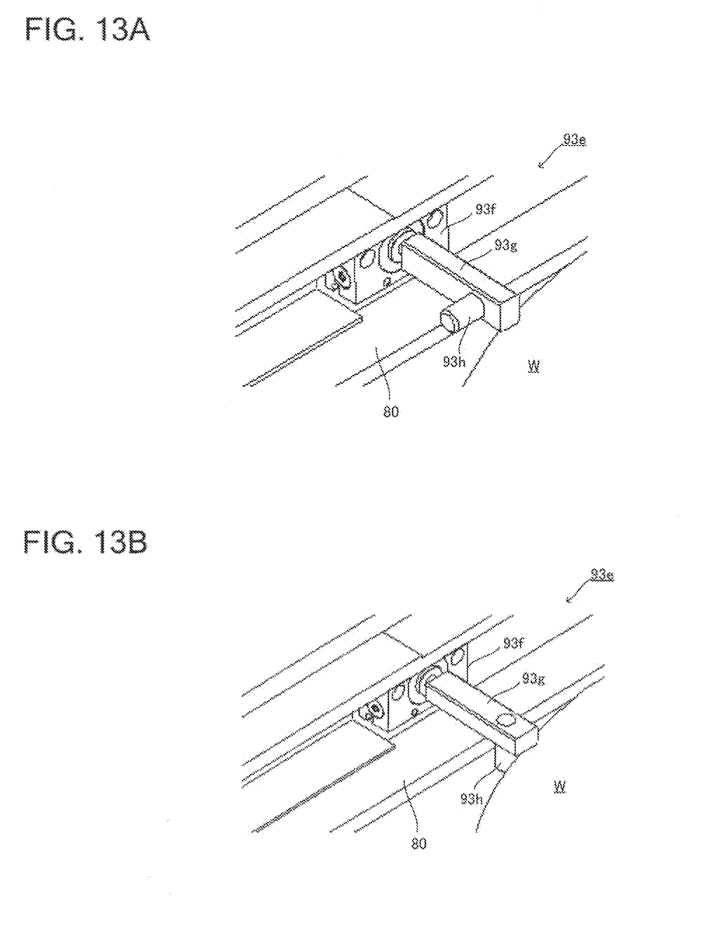

Then, as illustrated in FIGS. 12C-1 and 12C-2 and FIGS. 13A and 13B, a rotary actuator 93e carried on the second substrate holder conveying mechanism 93 presses the substrate W toward the leading end of the holder portion in the substrate holder 80 (a circular portion indicated by a dotted line in FIG. 12C-2). FIG. 13A and 13B is an enlarged view of the circular portion. As illustrated in FIG. 13A, the rotary actuator 93e includes a servomotor 93f, a rotating member 93g attached to an axis of rotation of the servomotor 93f, and a pin 93h projecting to the vicinity of a leading end of the rotating member 93g. When the substrate W is set in the substrate holder 80, the pin 93h faces in the horizontal direction, not to interfere with the substrate holder 80 and the substrate W. When the substrate W is set in the substrate holder 80, the servomotor 93f operates, to rotate the rotating member 93g, as illustrated in FIG. 13B. Thus, the pin 93h rotates, to contact the outer periphery of the substrate W. The pin 93h presses the substrate W so that the substrate W is reliably held in the substrate holder 80.

Then, as illustrated in FIGS. 12D-1 and 12D-2, the second substrate holder conveying mechanism 93 rises, to move to a transfer position of the substrate holder 80. The substrate conveying device 50a (50b) grips the gripped portions 85-1 and 85-2 in the substrate holder 80. In this state, the servomotor 93f in the rotary actuator 93e illustrated in FIG. 13A and 13B rotates backward so that the pin 93h retreats from the substrate holder 80. Simultaneously, the clampers 93b and 93c in the second substrate holder conveying mechanism 93 also retreat. Thus, the substrate holder 80 is gripped only by the substrate conveying device 50a (50b). The substrate conveying device 50a (50b) conveys the substrate holder 80 to the processing bath 66, as described above. Through the foregoing steps, a series of processes in which the substrate holder 80 is pulled out of the substrate holder receiving portion 67 and is finally conveyed to a processing unit ends.

The foregoing description has been made by paying attention to the one substrate holder 80. However, in the present embodiment, the second substrate holder conveying mechanism 93 includes two sets of clampers 93b and 93c. That is, the second substrate holder conveying mechanism 93 includes the upper clampers 93b and the lower clampers 93c. Therefore, an operation for gripping the substrate holder 80 that holds the substrate before processing in the lower clamper 93c while gripping the substrate holder 80 that holds the substrate after processing in the upper clamper 93b can be performed, for example. Thus, an operation for transferring the substrate holder 80 that holds the substrate before the processing to the substrate conveying device 50a (50b) and an operation for receiving the substrate holder 80 that holds the substrate after the processing from the substrate conveying device 50a (50b) can be performed in a short time. When the stocker 61 in the present embodiment is applied to a plating apparatus having a processing capability of approximately 150 sheets per hour, for example, the throughput of the plating apparatus can be improved to approximately 200 sheets per hour.

### Second Embodiment

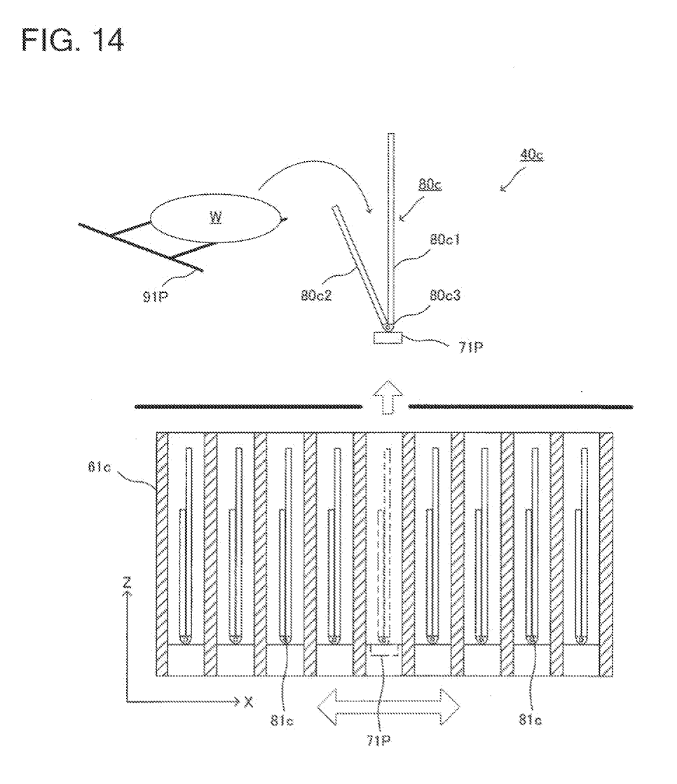

A second embodiment of the present invention will be described below with reference to FIG. 14. A substrate attaching/detaching unit 40c according to the present embodiment differs from that in the first embodiment in that a stocker 61c accommodates a substrate holder 80c in a vertical posture. That is, the stocker 61c in the present embodiment can accommodate a large number of substrate holders 80c respectively placed in a vertical posture side by side in a horizontal direction (an X-direction in the figure). FIG. 14 illustrates the stocker 61c that can accommodate the nine substrate holders 80c for convenience of illustration. The stocker 61c is adapted to be movable in the horizontal direction. When the substrate holder 80c to be used is desired to be selected, the substrate holder 80c can be positioned above an elevating mechanism 71P by horizontally moving the stocker 61c.

The elevating mechanism 71P rises to lift the substrate holder 80c upward (in a Z-direction in the figure) and falls to return the used substrate holder 80c to the stocker 61c. FIG. 14 illustrates a state where the fifth substrate holder 80c from the left has been lifted. The substrate holder 80c used in the present embodiment is of an open/close type, i.e., a substrate holder 80c including a holder body 80c1 and an opening/closing portion 80c2 that are connected via a turnable hinge 80c3. A slit-type substrate holder 80, described in the first embodiment, may be used.

A substrate transfer unit is positioned above the stocker 61c. The substrate transfer unit is used for mounting a substrate W, which is gripped with a robot hand 91P, on the substrate holder 80c. The substrate holder 80c receives the substrate W in an “open” state, i.e., a state for receiving the substrate W, and holds the substrate W in a “close” state, i.e., a state for holding the substrate W. An opening/closing mechanism for the substrate holder 80c can include a known (any) mechanism. When the substrate W, which has been processed, is removed from the substrate holder 80c, the robot hand 91P is also used. As described above, in the substrate attaching/detaching unit 40c according to the present embodiment, the stocker 61c is arranged below the substrate transfer unit. Thus, the footprint of the entire substrate attaching/detaching unit 40c can be kept small.

In a wet-type substrate processing apparatus that processes a substrate such as a semiconductor substrate, the present invention can be used for a substrate attaching/detaching unit that accommodates a substrate holder while mounting the substrate on the substrate holder.

### Third Embodiment

A substrate processing apparatus according to a third embodiment will be described below with reference to the drawings. The substrate processing apparatus according to the third embodiment has a similar configuration to the entire configuration of the wet-type substrate processing apparatus illustrated in FIG. 1. Thus, description of the entire configuration of the substrate processing apparatus is not repeated. In the substrate processing apparatus, a substrate holder 80 having a similar configuration to that of the substrate holder 80 described in FIGS. 5 and 6 is handled. The substrate processing apparatus according to the third embodiment has a feature in the substrate conveying devices 50a and 50b and the lifters 70 illustrated in FIG. 1, and hence the substrate conveying devices 50a and 50b and the lifters 70 will be specifically described.

<Lifter>

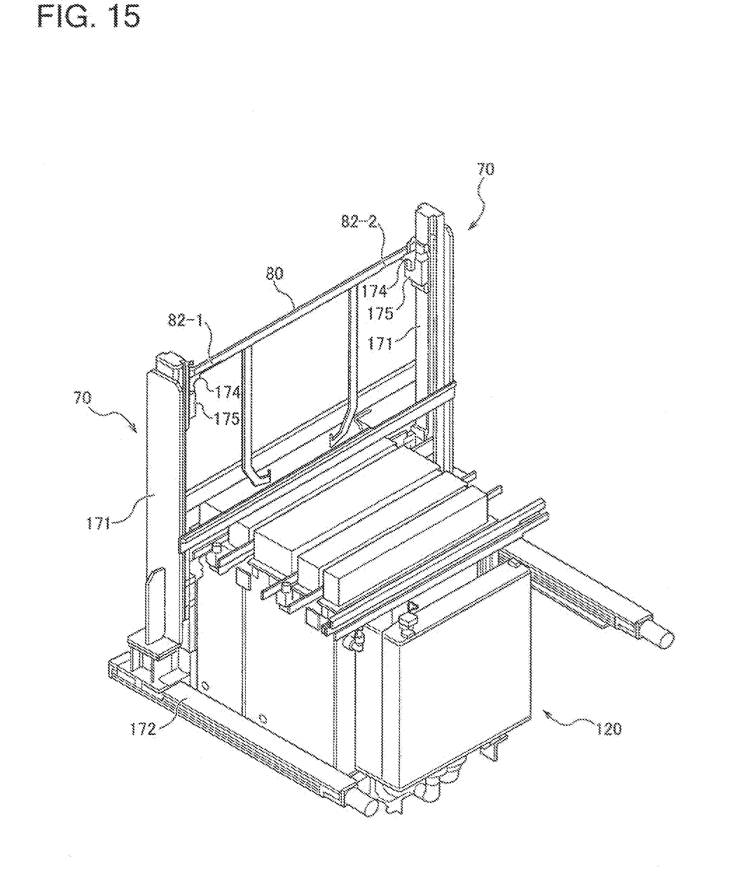

The lifters 70 respectively provided for each of pre-wetting baths 115a and 115b, the pre-wetting baths 145a and 145b, the etching module 120, and the resist stripping module 150 illustrated in FIG. 1 will be specifically described. FIG. 15 is a perspective view illustrating a lifter 70. To describe a positional relationship between the lifter 70 and a processing bath, an etching module 120 is also illustrated in FIG. 15 as an example of the processing bath.

As illustrated in FIG. 15, the lifter 70 includes a pair of rail portions 171 arranged on both sides of the etching module 120, slide portions 175 respectively slidably provided in the rail portions 171, support portions 174 respectively provided in the slide portions 175, and horizontal moving mechanisms 172 capable of respectively moving the rail portions 171 in a horizontal direction.

The horizontal moving mechanisms 172 are provided in the horizontal direction on both sides of the etching module 120. The pair of rail portions 171 is provided to extend in a vertical direction from the horizontal moving mechanisms 172. The rail portions 171 respectively have rails for sliding the slide portion 175 provided on their opposing sides. The slide portion 175 is adapted to be slidable up and down along the rail of the rail portion 171. The slide portion 175 is slid up and down by a driving device (not illustrated).

The support portion 174 in each of the rail portions 171 is a member formed to project toward the opposing rail portion 171, and supports arm portions 82-1 and 82-2 in a substrate holder 80 from below, as illustrated. That is, the substrate holder 80 is supported by the support portions 174 to be positioned between the rail portions 171.

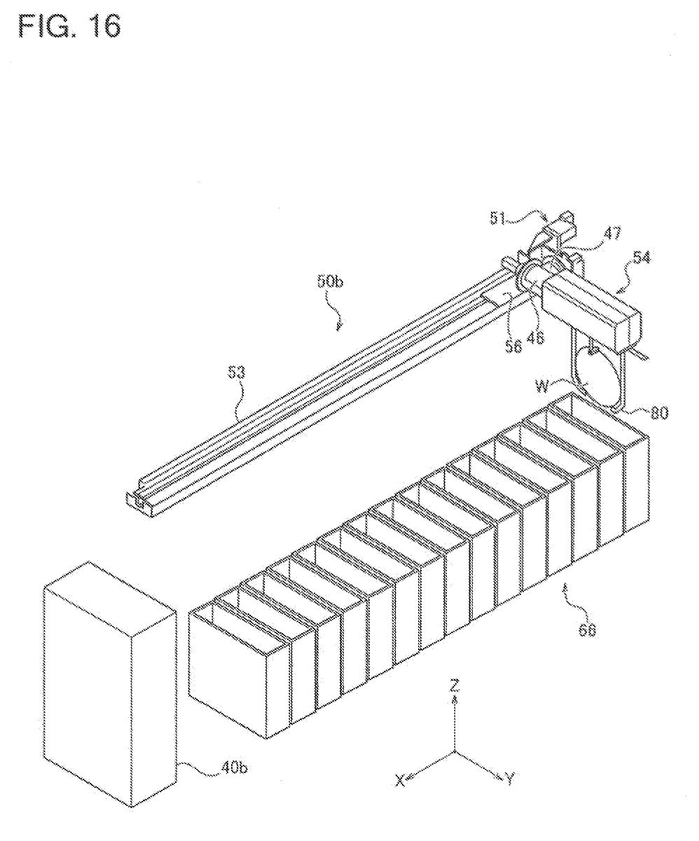

When the lifter 70 receives the substrate holder 80 from the substrate conveying devices 50a and 50b illustrated in FIG. 1, a holding mechanism 54 (see FIGS. 16 to 20) in each of the substrate conveying devices 50a and 50b first grips the substrate holder 80 so that a normal to a substrate surface of a substrate W faces in a substantially horizontal direction. The support portions 174 in the lifter 70, together with the slide portions 175, slide upward, to support the substrate holder 80 from below. When the holding mechanism 54 releases the gripping of the substrate holder 80 with the support portions 174 supporting the substrate holder 80, the substrate holder 80 is transferred to the support portions 174. Then, the lifter 70 lowers the substrate holder 80 to a height at which the substrate holder 80 does not interfere with the holding mechanism 54. Further, the lifter 70 moves the rail portions 171 in the horizontal direction by the horizontal moving mechanisms 172, as needed, to position the rail portions 171 beside a predetermined processing bath in the etching module 120. Thus, the substrate holder 80 is arranged directly above the predetermined processing bath. In this state, when the support portions 174 slide downward along the rail portions 171, the substrate holder 80 can be housed in the processing bath.

When the lifter 70 transfers the substrate holder 80 to the substrate conveying devices 50a and 50b illustrated in FIG. 1, the support portions 174 first respectively support the arm portions 82-1 and 82-2 in the substrate holder 80 housed in the processing bath in the etching module 120 from below. When the support portions 174 then rise along the rail portions 171, the substrate holder 80 is taken out of the processing bath. The horizontal moving mechanism 172 moves the rail portion 171 to a predetermined transfer position of each of the substrate conveying devices 50a and 50b, as needed, with the support portions 174 supporting the substrate holder 80. When the holding mechanism 54 in each of the substrate conveying devices 50a and 50b grips the substrate holder 80, and the support portions 174 in the lifter 70 then fall along the rail portions 171, the substrate holder 80 is transferred to the substrate conveying devices 50a and 50b.

<Substrate Conveying Device>

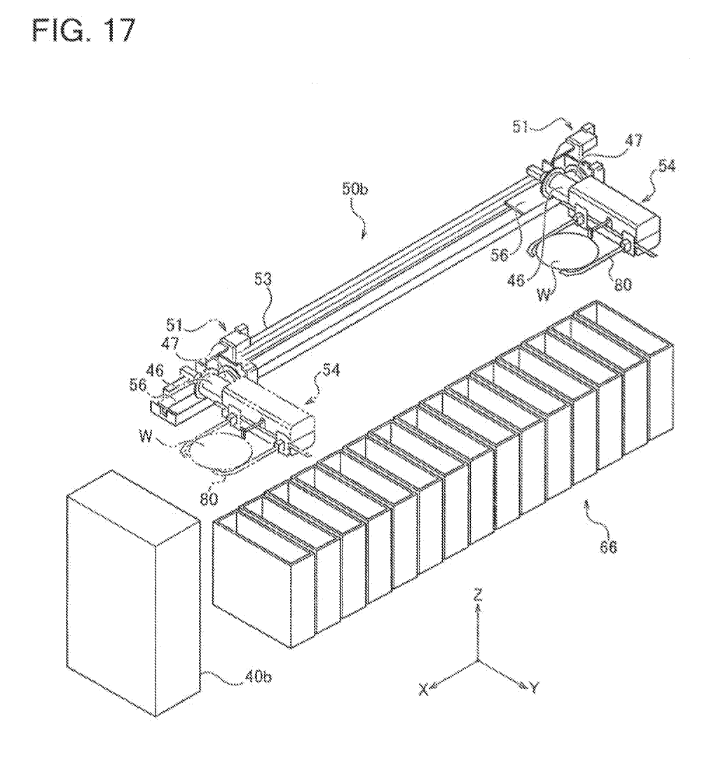

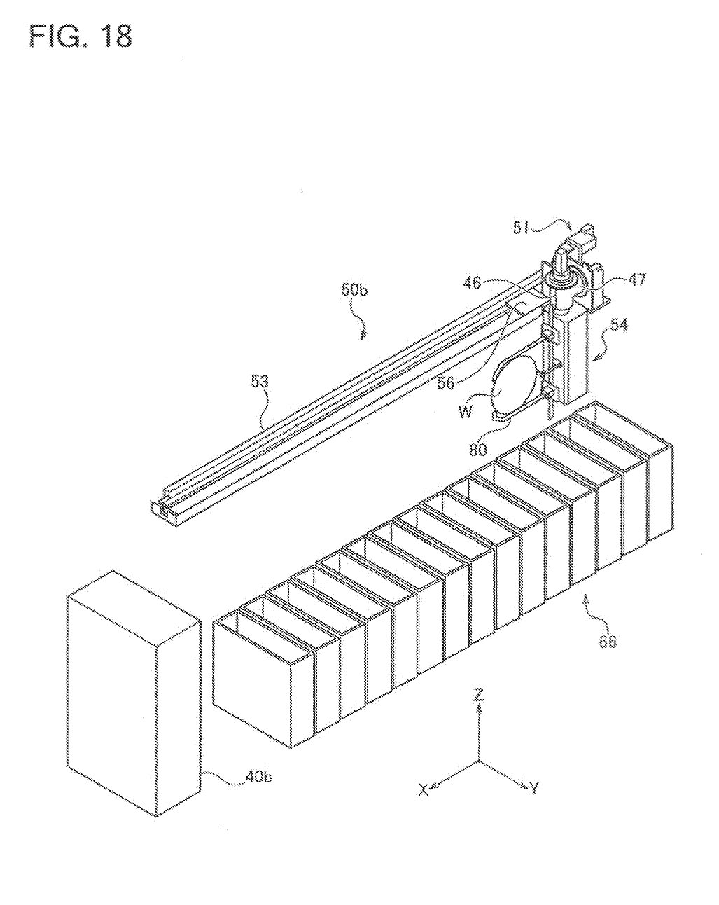

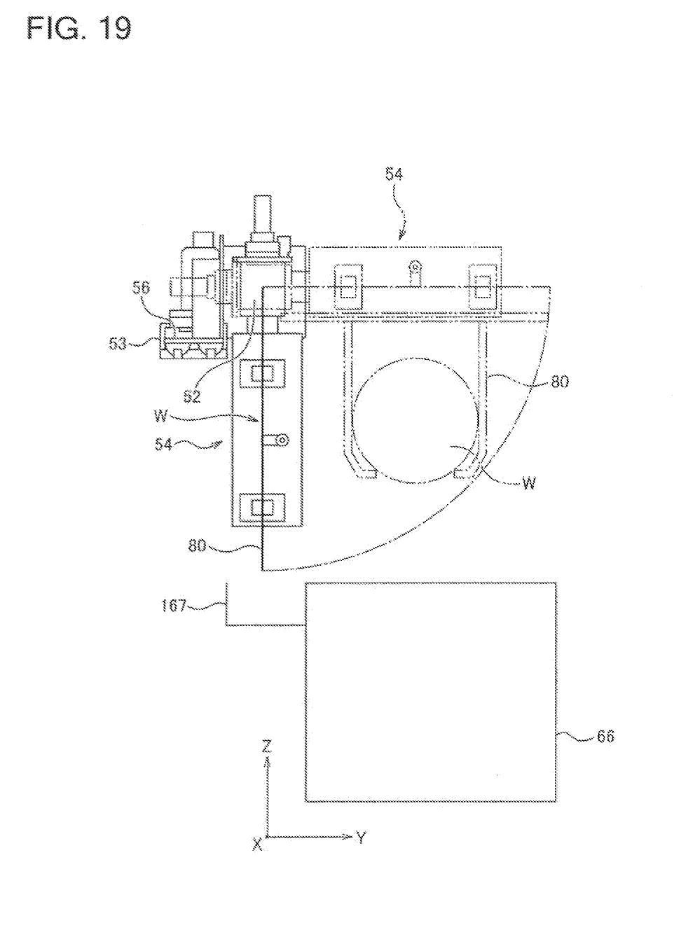

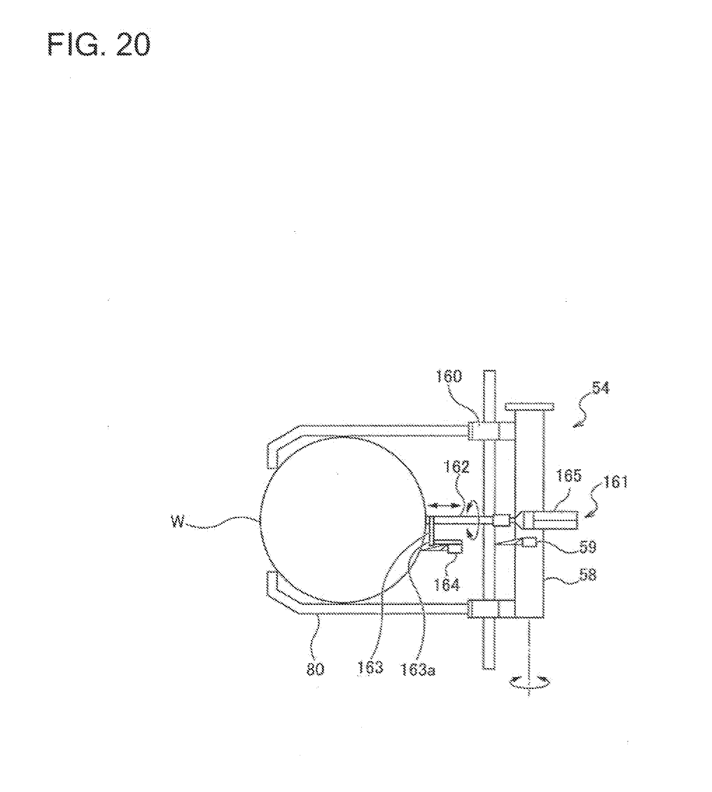

The substrate conveying device 50b illustrated in FIG. 1 will be described below. A substrate conveying device 50a has a similar configuration to that of the substrate conveying device 50b, and hence description thereof is not repeated. FIG. 16 is a perspective view of the substrate conveying device 50b illustrated in FIG. 1, FIG. 17 is a perspective view of the substrate conveying device 50b that holds the substrate W in the horizontal direction, FIG. 18 is a perspective view of the substrate conveying device 50b that holds the substrate W so that a normal to a substrate surface of a substrate W faces in the horizontal direction and faces in a direction perpendicular to a conveyance direction, FIG. 19 is a front view of the substrate conveying device 50b, and FIG. 20 is a partially enlarged view of the holding mechanism 54. In FIGS. 16 to 19, to describe a positional relationship between the processing bath and the substrate conveying device 50b, a processing bath 66 is illustrated for convenience. The processing bath 66 is a simplified illustration of the pre-wetting bath 115 or the etching module 120 illustrated in FIG. 1. The processing bath 66 includes a plurality of processing baths 66, and the number of processing baths 66 differs from that illustrated in FIG. 1. In FIGS. 16 to 18, the substrate attaching/detaching unit 40b is illustrated for convenience to describe a positional relationship between the substrate attaching/detaching unit 40b and the substrate conveying device 50b illustrated in FIG. 1.

As illustrated in FIG. 16, the processing bath 66 is adapted to accommodate the substrate W with a normal to the substrate W facing in a substantially horizontal direction. The plurality of processing baths 66 are arranged in a direction normal to the substrate W accommodated therein. By such a configuration, the substrate W is vertically processed so that air bubbles, which have adhered to the substrate W, successfully escape. The processing bath 66 is smaller in size than a face-down or face-up type device, and thus has a high processing capability with a small footprint.

As illustrated in FIGS. 16 to 18, the substrate conveying device 50b includes the holding mechanism 54 (corresponding to an example of a holding unit) that holds the substrate W by gripping the substrate holder 80, and a conveying mechanism 51 (corresponding to an example of a conveying unit) for conveying the substrate W held in the holding mechanism 54. The conveying mechanism 51 includes a traveling pedestal 56 to which the holding mechanism 54 is attached, and a guide rail 53 for guiding the traveling pedestal 56. The guide rail 53 is provided in a linear shape in a direction (an X-axis direction in the figure) substantially parallel to a direction in which the processing baths 66 line up. The substrate conveying device 50b includes a traveling motor (not illustrated) for traveling the traveling pedestal 56 on the guide rail 53. The holding mechanism 54, which holds the substrate W, can travel along the guide rail 53 from one end to the other end of the guide rail 53 by the conveying mechanism 51. Therefore, the conveying mechanism 51 can convey the substrate W in the direction in which the processing baths 66 line up (the X-axis direction in the figure). In the present embodiment, a direction in which the substrate W is conveyed is referred to as a conveyance direction. The conveyance direction matches the direction in which the processing baths 66 line up, the X-axis direction in the figure, and a direction of the guide rail 53.

The substrate conveying device 50b further includes a first driving mechanism 46 that swirls the holding mechanism 54 around an axis in the horizontal direction and the direction perpendicular to the conveyance direction (a Y-axis in the figure) and a second driving mechanism 47 that swirls the holding mechanism 54 around an axis in the conveyance direction (an X-axis in the figure). “The axis in the horizontal direction and the direction perpendicular to the conveyance direction” includes not only a case where the axis completely faces in the horizontal direction and faces in the direction perpendicular to the conveyance direction but also a case where the axis has a slight angle to the horizontal direction and the direction perpendicular to the conveyance direction. Similarly, “the axis in the conveyance direction” includes not only a case where the axis completely faces in the conveyance direction but also a case where the axis has a slight angle to the conveyance direction.

The holding mechanism 54 holds the substrate W with a normal to its substrate surface facing in the conveyance direction (the X-axis direction in the figure), as illustrated in FIG. 16, when it transfers the substrate holder 80 that holds the substrate W to and from the lifter 70 illustrated in FIG. 15.

The first driving mechanism 46 in the substrate conveying device 50b swirls the holding mechanism 54 in a state illustrated in FIG. 16 by approximately 90 degrees around the axis in the horizontal direction and the direction perpendicular to the conveyance direction (the Y-axis in the figure). Thus, as illustrated in FIG. 17, the holding mechanism 54 can hold the substrate W so that an in-plane direction of the substrate W is a substantially horizontal direction.

The second driving mechanism 47 in the substrate conveying device 50b swirls the holding mechanism 54 in a state illustrated in FIG. 17 by approximately 90 degrees around the axis in the conveyance direction (the X-axis in the figure). Thus, as illustrated in FIG. 18, the holding mechanism 54 can hold the substrate W so that the normal to the substrate surface of the substrate W faces in the horizontal direction and faces in the direction perpendicular to the conveyance direction. When the traveling motor is driven in this state, the traveling pedestal 56 travels along the guide rail 53. Thus, the conveying mechanism 51 conveys the substrate holder 80 and the substrate W with the normal to the substrate surface of the substrate W facing in the horizontal direction and facing in the direction perpendicular to the conveyance direction. In other words, the conveying mechanism 51 conveys the substrate holder 80 and the substrate W in the in-plane direction of the substrate W that is held in the vertical direction by the conveying mechanism 51 and the horizontal direction.

As illustrated in FIG. 19, when the holding mechanism 54 holds the substrate W (indicated by a solid line in the figure) so that the normal to the substrate surface of the substrate W faces in the horizontal direction and faces in the direction perpendicular to the conveyance direction, the holding mechanism 54 is adapted to hold the substrate W (the substrate holder 80) beside the processing bath 66. “Beside the processing bath 66” means a position deviating from a space directly above the processing bath 66. Further, when the lifter 70 illustrated in FIG. 15 is provided beside the processing bath 66, like in the present embodiment, “beside the processing bath 66” means a position deviating from a space directly above the processing bath 66 and a position not contacting the lifter 70. A liquid receiving pan 167 (corresponding to an example of a liquid receiving unit) is provided beside the processing bath 66. The holding mechanism 54 is adapted to hold the substrate W above a liquid receiving pan 167. The liquid receiving pan 167 receives a substrate processing liquid that falls from the substrate W conveyed above the liquid receiving pan 167. The liquid receiving pan 167 includes a drain (not illustrated), and is adapted to discharge the received substrate processing liquid.

A structure of the holding mechanism 54 will be specifically described below. As illustrated in FIG. 20, the holding mechanism 54 includes a rotating shaft 58 adapted to be rotatable by the first driving mechanism 46. The holding mechanism 54 can change the normal to the substrate surface of the held substrate W between the vertical direction and the horizontal direction when the rotating shaft 58 is rotated by the first driving mechanism 46 around its axis.

Furthermore, as illustrated in FIG. 20, the holding mechanism 54 includes a pair of holder clamps 160 provided in the rotating shaft 58, a substrate presser 161 that presses the substrate W against the substrate holder 80, and a holder detection sensor 59 that detects the presence or absence of the substrate holder 80. The holder clamp 160 grips gripped portions 85-1 and 85-2 (see FIG. 5) in the substrate holder 80. The holder detection sensor 59 includes an optical sensor or a magnetic sensor, for example, for detecting the presence or absence of the substrate holder 80 when the holder clamp 160 grips the substrate holder 80.

The substrate presser 161 includes a shaft portion 162, an air cylinder 165 that slides the shaft portion 162 along its axis and rotates the shaft portion 162 around the axis, a pressing portion 163 that presses the substrate W against the substrate holder 80 in contact with the substrate W, and a substrate detection sensor 164 that detects the presence or absence of the substrate W. The shaft portion 162 has its one end connected to the air cylinder 165 and its other end connected to the pressing portion 163. The pressing portion 163 is a bar-shaped member connected to the other end of the shaft portion 162 and having its end 163a extending in a direction substantially perpendicular to an axial direction of the shaft portion 162. The end 163a of the pressing portion 163 has a notch (not illustrated) on its surface contacting the substrate W. The substrate detection sensor 164 includes an optical sensor or a magnetic sensor, for example, fixed to the other end of the pressing portion 163 via fixing means.

When the holder clamp 160 in the holding mechanism 54 grips the substrate holder 80, the air cylinder 165 in the substrate presser 161 swirls the pressing portion 163 so that the end 163a of the pressing portion 163 is positioned on an edge of the substrate W. Then, the air cylinder 165 slides the shaft portion 162 in an axial direction so that the notch formed at the end 163a of the pressing portion 163 contacts the edge of the substrate W and the substrate W is pressed against the substrate holder 80.

When the holder clamp 160 releases the gripping of the substrate holder 80, the air cylinder 165 in the substrate presser 161 moves the shaft portion 162 upward and swirls the pressing portion 163, to release contact of the pressing portion 163 with the substrate W. The holding mechanism 54 releases the gripping of the substrate holder 80 of the holder clamp 160 when it transfers the substrate holder 80 to the lifter 70 (not illustrated).

A process for causing the substrate conveying device 50b to convey the substrate W will be described below. The holding mechanism 54 in the substrate conveying device 50b receives the substrate holder 80, which holds the substrate W, from the substrate attaching/detaching unit 40b illustrated in FIGS. 16 to 18, with the in-plane direction of the substrate W being the horizontal direction. At this time, the holding mechanism 54 in the substrate conveying device 50b holds the substrate W so that the in-plane direction of the substrate W faces in the horizontal direction (the conveyance direction in the figure), as illustrated in FIG. 17. As illustrated in FIG. 17, the substrate attaching/detaching unit 40b is positioned on an extension line of an array of the processing baths 66. When the holding mechanism 54 receives the substrate W from the substrate attaching/detaching unit 40b, the conveying mechanism 51 and the holding mechanism 54 are positioned at a leading end of the guide rail 53 (indicated by a broken line in FIG. 17).

When the holding mechanism 54 receives the substrate W from the substrate attaching/detaching unit 40b, the second driving mechanism 47 in the substrate conveying device 50b swirls the holding mechanism 54 around the axis in the conveyance direction (the X-axis in the figure). Thus, the holding mechanism 54 holds the substrate W so that the normal to the substrate surface of the substrate W faces in the horizontal direction and faces in the direction perpendicular to the conveyance direction, as illustrated in FIG. 18. The conveying mechanism 51 conveys the substrate holder 80 by passing the substrate holder 80 beside the processing bath 66 with the normal to the substrate surface of the substrate W facing in the horizontal direction and facing in the direction perpendicular to the conveyance direction.

The conveying mechanism 51 stops the holding mechanism 54 beside the predetermined processing bath 66. Then, the second driving mechanism 47 swirls the holding mechanism 54 around the axis in the conveyance direction (the X-axis in the figure). Thus, the holding mechanism 54 holds the substrate W so that the in-plane direction of the substrate W, as illustrated in FIG. 17, faces in the horizontal direction (the conveyance direction) (see FIG. 17). Further, the first driving mechanism 46 in the substrate conveying device 50b swirls the holding mechanism 54 around an axis in the horizontal direction and the direction perpendicular to the conveyance direction (the Y-axis in the figure). Thus, the holding mechanism 54 holds the substrate W with the normal to the substrate surface of the substrate W facing in the conveyance direction (the X-axis in the figure), as illustrated in FIG. 16. In this state, the substrate holder 80 is transferred to the lifter 70 (not illustrated) from the substrate conveying device 50b. The lifter 70 houses the received substrate holder 80 in the processing bath 66 with the normal to the substrate surface of the substrate W facing in the conveyance direction (the X-axis in the figure).

When the substrate W is then conveyed from the processing bath 66, the lifter 70 illustrated in FIG. 1 then takes out the substrate holder 80 from the processing bath 66. The holding mechanism 54 in the substrate conveying device 50b receives the substrate holder 80 from the lifter 70 with the normal to the substrate surface of the substrate W facing in the conveyance direction (the X-axis direction in the figure). Thus, the holding mechanism 54 holds the substrate W with the normal to the substrate surface of the substrate W facing in the conveyance direction (the X-axis direction in the figure), as illustrated in FIG. 16.

The first driving mechanism 46 in the substrate conveying device 50b is driven so that the holding mechanism 54 is swirled around the axis in the horizontal direction and the direction perpendicular to the conveyance direction (the Y-axis in the figure). Thus, the holding mechanism 54 holds the substrate W so that the in-plane direction of the substrate W is the horizontal direction (see FIG. 17). Then, the second driving mechanism 47 in the substrate conveying device 50b swirls the holding mechanism 54 around the axis in the conveyance direction (the X-axis in the figure). Thus, the holding mechanism 54 holds the substrate W so that the normal to the substrate surface of the substrate W faces in the horizontal direction and faces in the direction perpendicular to the conveyance direction, as illustrated in FIG. 18.

Furthermore, when the traveling motor is driven in this state, the traveling pedestal 56 travels along the guide rail 53. Thus, the conveying mechanism 51 conveys the substrate holder 80 and the substrate W to the other processing bath 66, for example, with the normal to the substrate surface of the substrate W facing in the horizontal direction and facing in the direction perpendicular to the conveyance direction.

As described above, in each of the substrate conveying devices 50a and 50b, the conveying mechanism 51 is adapted to convey the substrate W with the normal to the substrate surface of the substrate facing in the direction perpendicular to the conveyance direction. Thus, the area of the substrate W as viewed in the conveyance direction is reduced, and a space required to convey the substrate W can be reduced. Thus, the conveyance of the substrate W becomes difficult to obstruct by another substrate that is taken into and out of the processing bath 66. Consequently, in a limited space above the processing bath 66, the substrate W can be conveyed to avoid the other substrate that is taken into or out of the processing bath 66. Even if the substrate processing apparatus includes the lifters 70, like in the present embodiment, processing for taking in and out the substrate W by the lifter 70 and conveyance of the other substrate W by each of the substrate conveying devices 50a and 50b can be respectively performed at independent timings without interfering with each other. Even while the lifter 70 takes the substrate W into and out of the processing bath 66, therefore, the substrate processing apparatus need not wait for the conveyance of the other substrate W by each of the substrate conveying devices 50a and 50b. Thus, the throughput of the substrate processing apparatus can be improved. “The normal to the substrate surface of the substrate W faces in the direction perpendicular to the conveyance direction” includes not only a case where the normal to the substrate surface of the substrate W completely faces in the direction perpendicular to the conveyance direction but also a case where the normal to the substrate surface of the substrate W has a slight angle to the direction perpendicular to the conveyance direction.

In a conventional substrate processing apparatus, when a substrate is conveyed, the substrate is conveyed above the processing bath with a normal to a substrate surface of the substrate facing in a direction parallel to a conveyance direction. In this case, the normal to the substrate surface matches the conveyance direction. When the substrate is conveyed, therefore, the surface of the substrate W easily contacts particles in a space. Thus, a large number of particles may adhere to the surface of the substrate. On the other hand, in the substrate processing apparatus according to the present embodiment, the normal to the substrate surface of the substrate W during the conveyance does not face in the conveyance direction. Thus, the substrate surface of the substrate W does not easily contact particles in the air during the conveyance. Therefore, a large number of particles can be inhibited from adhering to the substrate surface. Further, the area of the substrate W as viewed in the conveyance direction of the substrate W during the conveyance is reduced. Thus, an air resistance, which the substrate W gets by the conveyance, can be reduced so that the substrate W can be conveyed at a relatively high speed.

In the present embodiment, the holding mechanism 54 is adapted to hold the substrate W with the normal to the substrate surface of the substrate W facing in the horizontal direction and facing in the direction perpendicular to the conveyance direction. Thus, in a limited space above the processing bath 66, the substrate W to be conveyed can be prevented from interfering with the other substrate that is taken into and out of the processing bath 66 only by conveying the substrate W with the substrate W shifted sideward from the other substrate W. Even while the substrate W is taken into and out of the processing bath 66, therefore, the substrate W need not wait for the conveyance of the other substrate W. Thus, the throughput of the substrate processing apparatus can be improved. The normal to the substrate surface of the substrate W does not face in the vertical direction. Thus, a contact area between particles that fall with a weight and the substrate W can be reduced so that the particles can be inhibited from adhering to the surface of the substrate W. “The normal to the substrate surface of the substrate W facing in the horizontal direction” includes not only a case where the normal to the substrate surface of the substrate W completely facing in the horizontal direction but also a case where the normal to the substrate surface of the substrate W has a slight angle to the horizontal direction.

In the present embodiment, the holding mechanism 54 holds the substrate W beside the processing bath 66. Thus, the other substrate W, which is taken into and out of the processing bath 66, can be prevented from interfering with the substrate W that is being conveyed. The holding mechanism 54 holds the substrate W beside the processing bath 66. Therefore, a substrate processing liquid, which has adhered to the substrate W, does not fall on the processing bath 66. In the present embodiment, the liquid receiving pan 167 is provided beside the processing bath 66, and the substrate W is held above the liquid receiving pan 167. Therefore, the liquid receiving pan 167 can receive the substrate processing liquid, which has fallen from the substrate W, so that the substrate processing liquid can be prevented from being scattered.

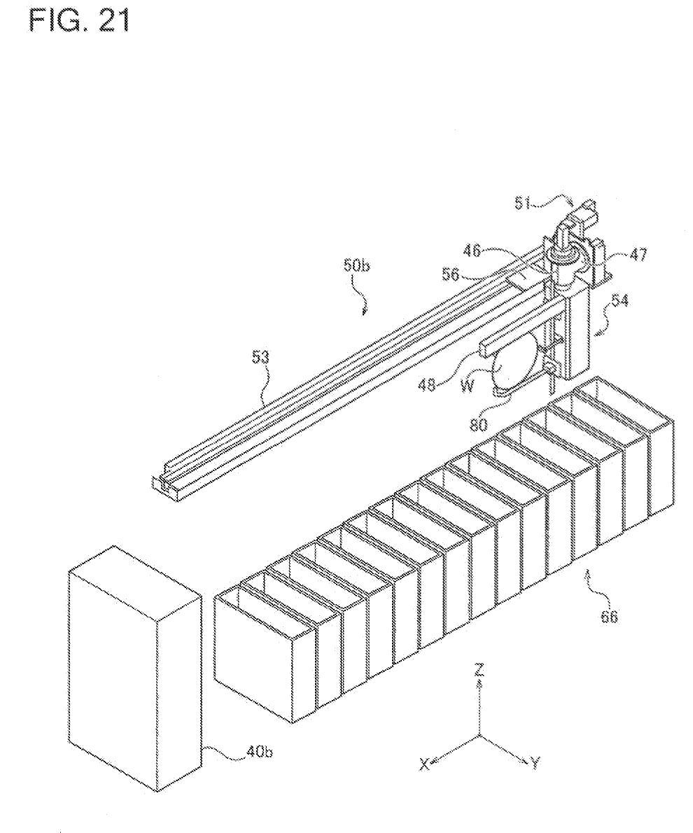

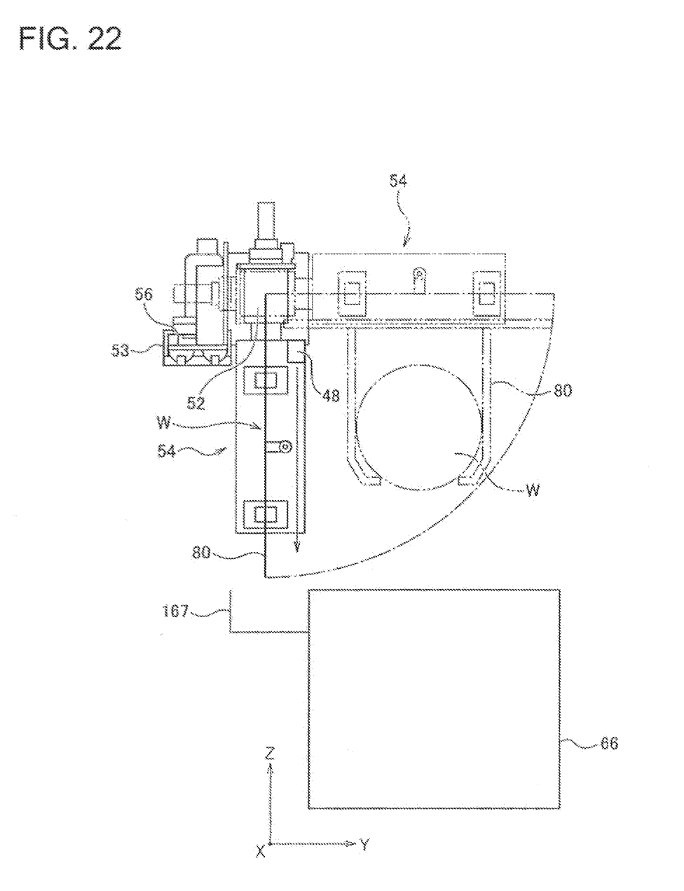

A modified example of each of the substrate conveying devices 50a and 50b according to the third embodiment will be described below. FIG. 21 is a perspective view of a substrate conveying device 50b including a first gas jetting unit, and FIG. 22 is a front view of the substrate conveying device 50b including the first gas jetting unit. Each of the substrate conveying devices 50a and 50b in the third embodiment can additionally include the first gas jetting unit illustrated in FIGS. 21 and 22.

As illustrated in FIG. 21, a first gas jetting unit 48 is positioned above a substrate W and extends in a horizontal direction along a substrate surface of a substrate W while a holding mechanism 54 holds the substrate W so that a normal to the substrate surface of the substrate W faces in a horizontal direction and faces in a direction perpendicular to a conveyance direction. As illustrated in FIG. 22, the first gas jetting unit 48 is positioned between a surface, on the side of a processing bath 66, of the substrate W and the processing bath 66. The first gas jetting unit 48 has a plurality of holes for jetting gas (e.g., air) on its lower side and is adapted to jet gas vertically downward in a positional relationship illustrated in FIGS. 21 and 22. When the first gas jetting unit 48 jets gas vertically downward, an air curtain can be formed between the substrate W held so that the normal to the substrate surface of the substrate W faces in the horizontal direction and faces in the direction perpendicular to the conveyance direction and the processing bath 66, and the substrate W and the processing bath 66 can be atmospherically separated from each other.

In the modified example illustrated in FIGS. 21 and 22, the first gas jetting unit 48 atmospherically separates the substrate W and the processing bath 66. Thus, the lifter 70 illustrated in FIG. 15 can inhibit a substrate processing liquid atmosphere, which is diffused by taking the substrate W into and out of the processing bath 66, from contacting the substrate W to be conveyed.

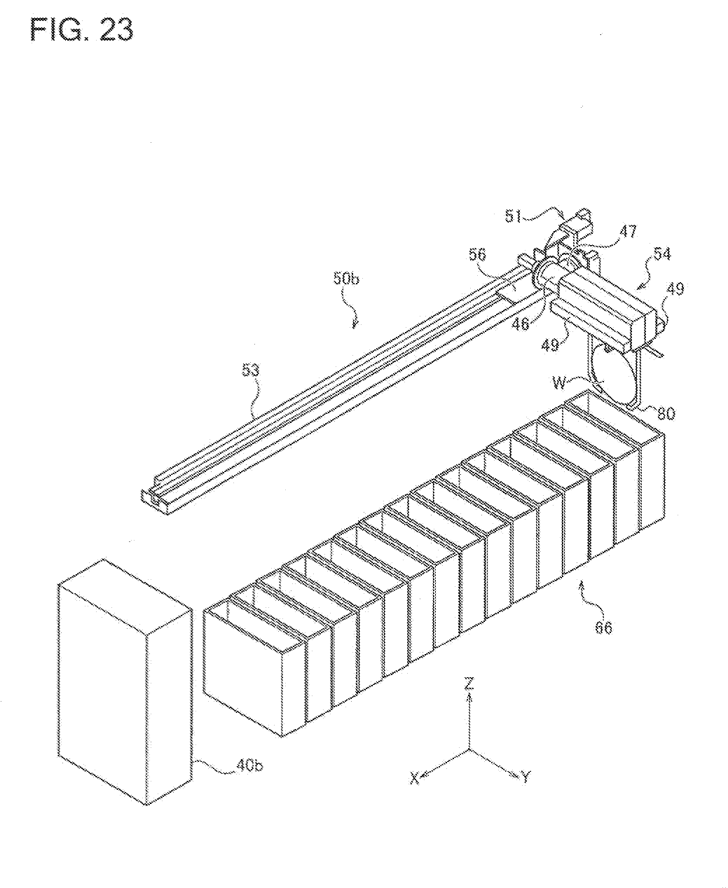

Another modified example of each of the substrate conveying devices 50a and 50b according to the third embodiment will be described below. FIG. 23 is a perspective view of a substrate conveying device 50b including a second gas jetting unit. Each of the substrate conveying devices 50a and 50b according to the third embodiment and the substrate conveying devices 50a and 50b in the modified example illustrated in FIGS. 21 and 22 can additionally include a second gas jetting unit illustrated in FIG. 23.

As illustrated in FIG. 23, a second gas jetting unit 49 is positioned above a substrate W and extends in a horizontal direction along a substrate surface of the substrate W while a holding mechanism 54 holds the substrate W so that a normal to the substrate surface of the substrate W faces in a conveyance direction (an X-axis direction in the figure). Second gas jetting units 49 are respectively provided on both sides of the substrate W. The second gas jetting unit 49 has a plurality of holes for jetting gas (e.g., air) on its lower side and is adapted to jet gas vertically downward in a positional relationship illustrated in FIG. 23. Therefore, the second gas jetting unit 49 can jet gas vertically downward in an in-plane direction on both sides of the substrate W.

The second gas jetting unit 49 is adapted to jet gas vertically downward in the in-plane direction on both sides of the substrate W when the substrate conveying device 50b receives a substrate holder 80 from the lifter 70 illustrated in FIG. 15. Thus, an air curtain is formed on both surfaces of the substrate W so that particles can be inhibited from adhering to both surfaces of the substrate W. Gas can be jetted to both sides of the substrate W that has just been taken out of a processing bath 66. Therefore, a substrate processing liquid, which has adhered to the substrate W, can be drained.

### Fourth Embodiment

A substrate processing apparatus according to a fourth embodiment of the present invention will be described below with reference to the drawings. The substrate processing apparatus according to the fourth embodiment differs from the substrate processing apparatus according to the third embodiment in terms of a configuration of each of substrate conveying devices 50a and 50b. The other configuration is similar to that in the third embodiment, and hence, illustration and description are not repeated for similar components to those in the third embodiment, and the substrate conveying devices 50a and 50b serving as different components will be described.

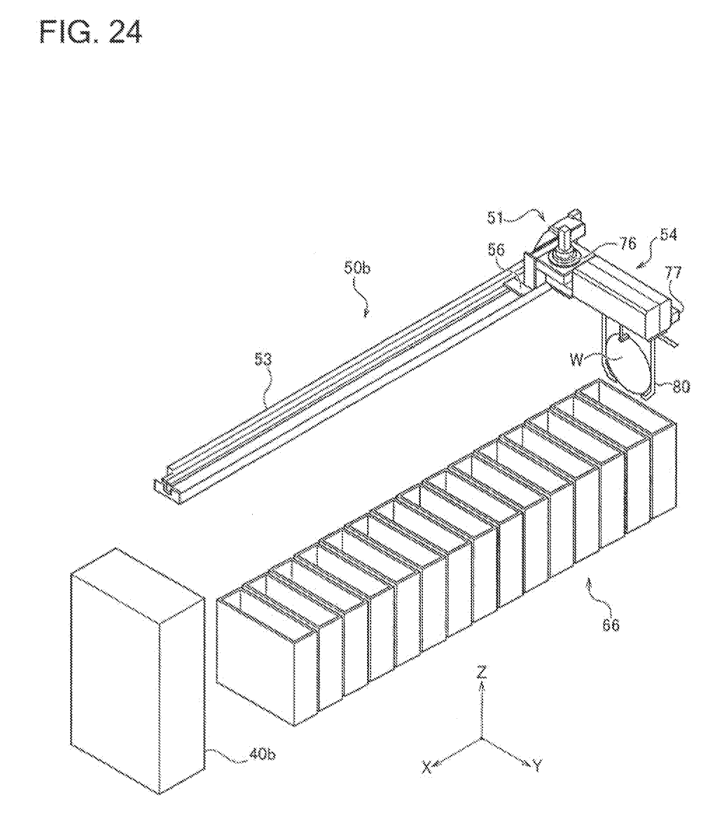

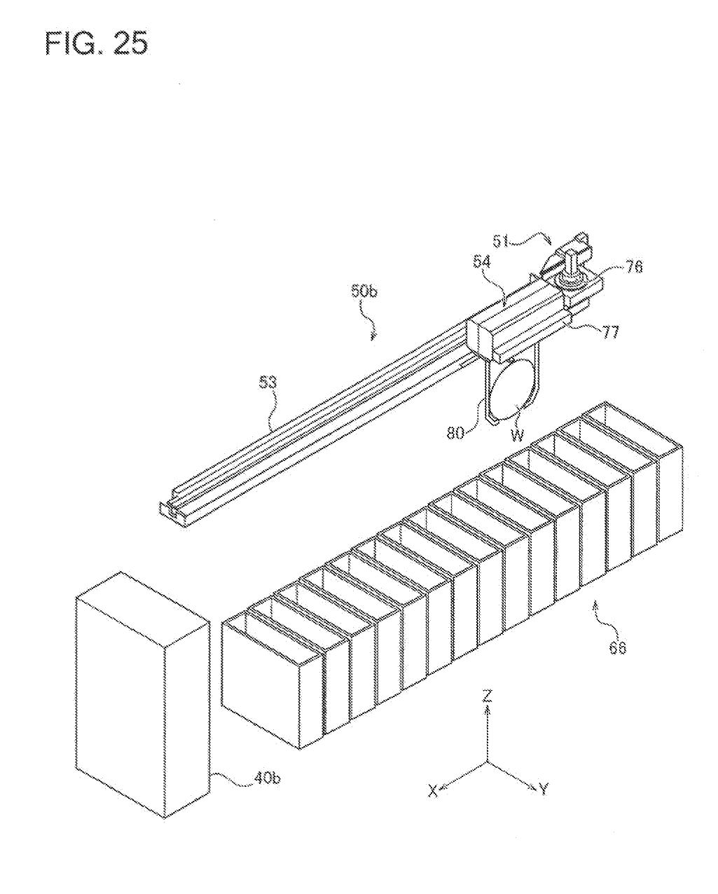

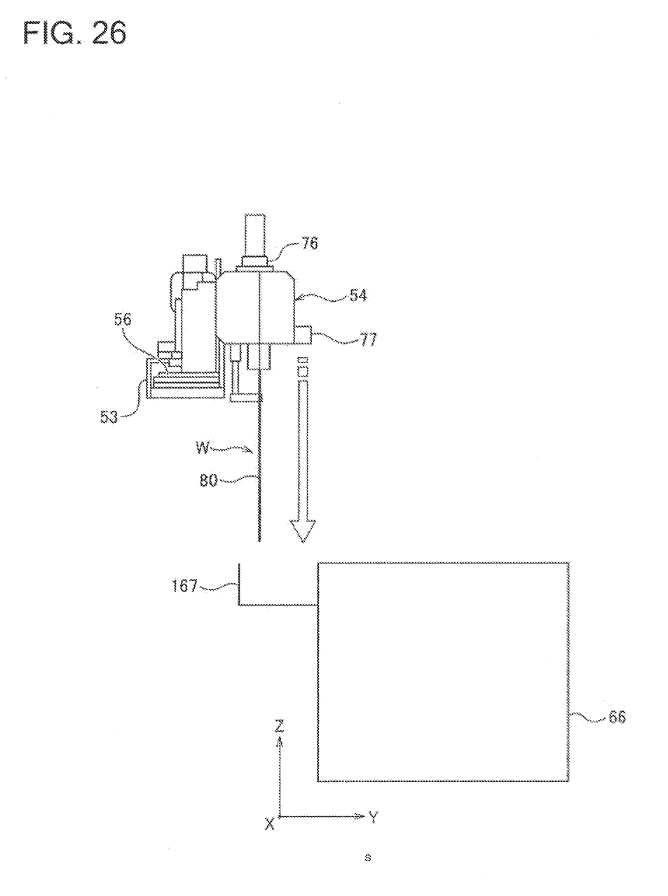

FIG. 24 is a perspective view of the substrate conveying device 50b in the substrate processing apparatus according to the fourth embodiment, FIG. 25 is a perspective view of the substrate conveying device 50b that holds a substrate W in a conveyance direction, and FIG. 26 is a front view of the substrate conveying device 50b.

As illustrated in FIGS. 24 and 25, the substrate conveying device 50b includes a third driving mechanism 76 that swirls a holding mechanism 54 around an axis in a vertical direction (a Z-axis in the figure) instead of the first driving mechanism 46 and the second driving mechanism 47 described in the third embodiment. “The axis in the vertical direction” includes not only a case where the axis completely faces in the vertical direction but also a case where the axis has a slight angle to the vertical direction.

The holding mechanism 54 holds the substrate W with a normal to a substrate surface of a substrate W facing in the conveyance direction (an X-axis direction in the figure), as illustrated in FIG. 24, when it transfers a substrate holder 80, which holds the substrate W, to and from the lifter 70 illustrated in FIG. 15.

The third driving mechanism 76 in the substrate conveying device 50b swirls the holding mechanism 54 in a state illustrated in FIG. 24 by approximately 90 degrees around the axis in the vertical direction (the Z-axis in the figure). Thus, as illustrated in FIG. 25, the holding mechanism 54 can hold the substrate W so that the normal to the substrate surface of the substrate W faces in a horizontal direction and faces in a direction perpendicular to the conveyance direction. In this state, a traveling motor is driven so that a traveling pedestal 56 travels along a guide rail 53. Thus, a conveying mechanism 51 conveys the substrate holder 80 and the substrate W with the normal to the substrate surface of the substrate W facing in the horizontal direction and facing in the direction perpendicular to the conveyance direction.

As illustrated in FIG. 26, when the holding mechanism 54 holds the substrate W so that the normal to the substrate surface of the substrate W faces in the horizontal direction and faces in the direction perpendicular to the conveyance direction, the holding mechanism 54 is adapted to hold the substrate W beside a processing bath 66, like in the third embodiment.

The substrate conveying device 50b includes a first gas jetting unit 77 that is provided in the holding mechanism 54, is positioned above the substrate W, and extends in the horizontal direction along the surface of the substrate W. The first gas jetting unit 77 is positioned between a surface on the side of the processing bath 66 of the substrate W and the processing bath 66 with the holding mechanism 54 holding the substrate W so that the normal to the substrate surface of the substrate W faces in the horizontal direction and faces in the direction perpendicular to the conveyance direction, as illustrated in FIGS. 25 and 26. The first gas jetting unit 77 has a plurality of holes for jetting gas (e.g., air) on its lower side, and is adapted to jet gas vertically downward. When the first gas jetting unit 77 jets gas vertically downward in a state illustrated in FIG. 26, an air curtain can be formed between the substrate W and the processing bath 66 so that the substrate W and the processing bath 66 can be atmospherically separated from each other.

The substrate conveying device 50b according to the fourth embodiment has a similar advantage to that of the substrate conveying device 50b described in FIGS. 16 to 20. In addition, in the substrate conveying device 50b according to the fourth embodiment, the holding mechanism 54 can hold the substrate W so that the normal to the substrate surface of the substrate W faces in the horizontal direction and faces in the direction perpendicular to the conveyance direction when the holding mechanism 54 is swirled around one axis by the third driving mechanism 76. Therefore, the substrate conveying device 50b according to the fourth embodiment can more quickly change a holding position of the substrate W than the substrate conveying device 50b according to the first embodiment in which the holding mechanism 54 is swirled around two axes by the first driving mechanism 46 and the second driving mechanism 47. Further, the substrate conveying device 50b according to the second embodiment can reduce the number of driving mechanisms by one from that in the first embodiment. Therefore, the cost can be reduced.

The substrate conveying device 50b according to the second embodiment can atmospherically separate the substrate W and the processing bath 66 using the first gas jetting unit 77. Thus, the lifter 70 illustrated in FIG. 15 can inhibit a substrate processing liquid atmosphere, which is diffused by taking the substrate W into and out of the processing bath 66, from contacting the substrate W to be conveyed.

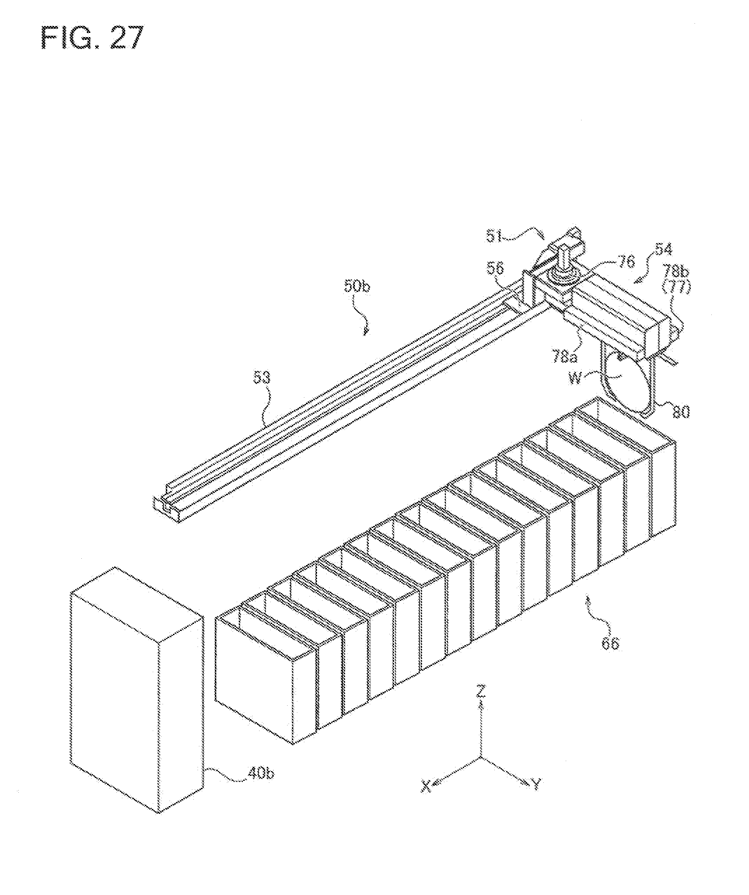

A modified example of each of the substrate conveying devices 50a and 50b according to the fourth embodiment will be described below. FIG. 27 is a perspective view of a substrate conveying device 50b including a second gas jetting unit. Each of the substrate conveying devices 50a and 50b according to the fourth embodiment can additionally include a second gas jetting unit illustrated in FIG. 27.

As illustrated in FIG. 27, a pair of second gas jetting units 78a and 78b is positioned above a substrate W, and extends in the horizontal direction along a surface of the substrate W. The second gas jetting units 78a and 78b are provided on both sides of the substrate W. Each of the second gas jetting units 78a and 78b has a plurality of holes for jetting gas (e.g., air) on its lower side, and is adapted to jet gas vertically downward. Therefore, the second gas jetting units 78a and 78b can jet gas vertically downward in an in-plane direction on both sides of the substrate W.

The second gas jetting units 78a and 78b are adapted to jet gas vertically in the in-plane direction on both sides of the substrate W when the substrate conveying device 50b receives a substrate holder 80 from the lifter 70 illustrated in FIG. 15. Thus, an air curtain is formed on both surfaces of the substrate W so that particles can be inhibited from adhering to both surfaces of the substrate W. Gas can be jetted to both sides of the substrate W that has just been taken out of the processing bath 66. Therefore, a substrate processing liquid, which has adhered to the substrate W, can be drained.

When the holding mechanism 54 holds the substrate W so that the normal to the substrate surface of the substrate W faces in the horizontal direction and faces in the direction perpendicular to the conveyance direction, like in a state illustrated in FIG. 26, the second gas jetting unit 78b illustrated in FIG. 27 jets gas so that the substrate W and the processing bath 66 can be atmospherically separated from each other. That is, the second gas jetting unit 78b can also produce a similar function to that of the first gas jetting unit 77 illustrated in FIG. 26.

Although the embodiments of the present invention have been described above, the above-mentioned embodiments of the invention are used for making understanding of the present invention easy and not limiting the present invention. It should be noted that the present invention can be altered and improved without departing from the scope of the present invention and includes its equivalent. In a range in which at least some of the above-mentioned issues can be solved or a range in which at least some of effects are produced, any combination or omission of components described in the claims and the specification are possible.

While the substrate holder 80 holds and processes the substrate W in the above-mentioned embodiments, the substrate holder 80 need not necessarily be required, and the holding mechanism 54 may be adapted so that the substrate W can be directly held. That is, in the present invention, the holding mechanism 54 includes a holding mechanism 54 that directly holds the substrate W and a holding mechanism 54 that indirectly holds the substrate W via the substrate holder 80.

In the above-mentioned embodiments, when the substrate W is positioned beside the processing bath, the substrate W is held so that the normal to the substrate surface of the substrate W faces in the horizontal direction and faces in the direction perpendicular to the conveyance direction. However, when a sufficient conveyance space exists, for example, the normal to the substrate surface of the substrate W need not face in the horizontal direction and the direction perpendicular to the conveyance direction. That is, even if the substrate W can be positioned beside the processing bath, the substrate W conveyed beside the processing bath and the substrate W that is taken into and out of the processing bath 66 do not interfere with each other. Thus, in this case, the substrate W may face in any direction.

### REFERENCE SIGNS LIST

1 wet-type substrate processing apparatus

40a, 40b, 40c substrate attaching/detaching unit

46 first driving mechanism

47 second driving mechanism

48, 77 first gas jetting unit

49, 78a, 78b second gas jetting unit

50a, 50b substrate conveying device

51 conveying mechanism

54 holding mechanism

61, 61c stocker

65a, 65b, 65c, 65d columnar member

66 processing bath

67 holder receiving portion

71 first substrate holder conveying mechanism

71a elevating base

71b base driving cylinder

71c cylinder base

71d holder clamp cylinder

71e1, 71e2 clamp member

71P elevating mechanism

75a linear guide

75b threaded shaft

76 third driving mechanism

80, 80c substrate holder

91 substrate attaching/detaching mechanism

91a linear guide

91b actuator

91c base

91d substrate guide

91e center pin

93 second substrate holder conveying mechanism

93a base

93b, 93c clamper

93d clamper driving cylinder

93e rotary actuator

167 liquid receiving pan

W substrate

What is claimed is:

1. A substrate attaching/detaching unit comprising:
a stocker accommodating a plurality of substrate holders and adapted so that the substrate holders are aligned in a vertical direction with one another in a horizontal posture;
a first substrate holder conveying mechanism that takes the substrate holder into and out of the stocker;
an elevating mechanism that raises and lowers the first substrate holder conveying mechanism in the vertical direction;
a second substrate holder conveying mechanism that transfers the substrate holder to and from the first substrate holder conveying mechanism; and
a substrate attaching/detaching mechanism that attaches and detaches the substrate to and from the substrate holder held in the second substrate holder conveying mechanism.

2. The substrate attaching/detaching unit according to claim 1, further comprising a plurality of substrate holder accommodating portions that respectively accommodate the plurality of substrate holders, wherein each of the substrate holder accommodating portions includes holder receiving portions at at least three points, the respective heights of which are equal to one another.

3. The substrate attaching/detaching unit according to claim 1, wherein the substrate holder includes a linear first portion and two second portions each extending in a direction substantially perpendicular to the first portion and having a leading end bent in a hook shape, the substrate being held between the two second portions, and the holder receiving portion receives both ends of the first portion and the leading ends of the second portions.

4. The substrate attaching/detaching unit according to claim 1, wherein the first substrate holder conveying mechanism holds the substrate holder at three points from inside the first portion and the second portions, and is movable in the vertical direction by the elevating mechanism.

5. The substrate attaching/detaching unit according to claim 1, wherein the substrate attaching/detaching mechanism includes a base member, a linear guide that movably supports the base member in a linear direction, an actuator that moves the base member along the linear guide, and a substrate guide that is arranged on the base member to hold the substrate in a horizontal posture.

6. The substrate attaching/detaching unit according to claim 3, wherein the second substrate holder conveying mechanism includes a clamper that holds the two second portions from outside, and a rotary actuator for pressing the substrate toward the leading ends of the second portions.

7. The substrate attaching/detaching unit according to claim 1, wherein the second substrate holder conveying mechanism includes two sets of chucks that hold the substrate holders.

8. The substrate attaching/detaching unit according to claim 1, wherein the elevating mechanism includes a linear guide extending in the vertical direction, a ball screw coupled to the first substrate holder conveying mechanism, a threaded shaft threadably mounted on the ball screw and extending in the vertical direction, and an electric motor that rotates the threaded shaft via a timing belt.

9. The substrate attaching/detaching unit according to claim 1, wherein the stocker is provided below the substrate attaching/detaching mechanism and the second substrate holder conveying mechanism.

10. A wet-type substrate processing apparatus comprising:
a substrate holder that holds a substrate;
a processing bath accommodating the substrate holder to perform processing;
a conveying machine that conveys the substrate holder to the processing bath; and
the substrate attaching/detaching unit according to claim 1.

11. The wet-type substrate processing apparatus according to claim 10, further comprising:
a second elevating mechanism that raises and lowers the second substrate holder conveying mechanism in the vertical direction;
wherein the second elevating mechanism is adapted to transfer the substrate holder that holds the substrate to the conveying machine.

12. The wet-type substrate processing apparatus according to claim 10, wherein the second substrate holder conveying mechanism includes two sets of chucks each holding the substrate holder.

13. A substrate holder conveying method using the wet-type substrate processing apparatus according to claim 12, wherein
the second substrate holder conveying mechanism receives a first substrate holder that grips the substrate before the processing with one of the sets of chucks while receiving a second substrate holder that grips the substrate after the processing with the other set of chucks, and
transfers the first substrate holder to the conveying machine while removing the substrate from the second substrate holder, and transfers the second substrate holder to the first substrate holder conveying mechanism.

14. A substrate processing apparatus comprising:
a conveying machine including a holding unit that holds a substrate and a conveying unit that conveys the substrate held by the holding unit; and
a processing bath that houses the substrate with a normal to its substrate surface facing in a conveyance direction, to process the substrate, wherein
the holding unit is adapted to hold the substrate with the normal to the substrate surface facing in a horizontal direction and facing in a direction perpendicular to the conveyance direction, and
the conveying unit is adapted to convey the substrate with the normal to the substrate surface facing in the horizontal direction and facing in the direction perpendicular to the conveyance direction.

15. The substrate processing apparatus according to claim 14, wherein the holding unit is adapted to hold the substrate beside the processing bath when the conveying unit conveys the substrate with the normal to the substrate surface facing in the horizontal direction and facing in the direction perpendicular to the conveyance direction.

16. The substrate processing apparatus according to claim 15, further comprising
a liquid receiving unit provided beside the processing tank,
wherein the holding unit is adapted to hold the substrate above the liquid receiving unit when the conveying unit conveys the substrate with the normal to the substrate surface facing in the horizontal direction and facing in the direction perpendicular to the conveyance direction.

17. The substrate processing apparatus according to claim 15, further comprising a first gas jetting unit forming an air curtain for atmospherically separating the substrate, which is held with the normal to the substrate surface facing in the horizontal direction and facing in the direction perpendicular to the conveyance direction, and the processing bath.

18. The substrate processing apparatus according to claim 14, further comprising a second gas jetting unit for spraying gas in an in-plane direction on both sides of the substrate when the substrate is positioned above the processing bath.

19. The substrate processing apparatus according to claim 14, wherein the conveying machine includes a first driving mechanism that swirls the holding unit around its axis in the horizontal direction and the direction perpendicular to the conveyance direction and a second driving mechanism that swirls the holding unit around its axis in the conveyance direction.

20. The substrate processing apparatus according to claim 14, wherein the conveying machine includes a third driving mechanism that swirls the holding unit around its axis in a vertical direction.

21. A substrate conveying method comprising the steps of:
conveying a substrate with a normal to its substrate surface facing in a horizontal direction and facing in a direction perpendicular to a conveyance direction;
swirling the substrate so that the normal to the substrate surface faces in the conveyance direction; and
housing the substrate in a processing bath with the normal to the substrate surface facing in the conveyance direction.

22. A substrate processing apparatus comprising:
a substrate holder that holds a substrate;
a conveying machine including a holding unit that holds the substrate holder and a conveying unit that conveys the substrate holder held in the holding unit; and
a processing bath that houses the substrate and the substrate holder with a normal to its substrate surface facing in a conveyance direction of the conveying machine, to process the substrate,
wherein the holding unit is adapted to hold the substrate beside the processing bath when the conveying unit conveys the substrate.

23. The substrate processing apparatus according to claim 22, further comprising a liquid receiving unit provided beside the processing bath,
wherein the holding unit is adapted to hold the substrate above the liquid receiving unit when the conveying unit conveys the substrate.

24. The substrate processing apparatus according to claim 22, further comprising a first gas jetting unit forming an air curtain for atmospherically separating the substrate and the processing bath from each other when the conveying unit conveys the substrate.

25. The substrate processing apparatus according to claim 22, further comprising a second gas jetting unit that sprays gas in an in-plane direction on both sides of the substrate when the substrate is positioned above the processing bath.

26. The substrate processing apparatus according to claim 22, wherein
the holding unit is adapted to hold the substrate with the normal to the substrate surface facing in the direction perpendicular to the conveyance direction, and
the conveying unit is adapted to convey the substrate with the normal to the substrate surface facing in the direction perpendicular to the conveyance direction.

27. The substrate processing apparatus according to claim 26, wherein the holding unit is adapted to hold the substrate with the normal to the substrate surface facing in a horizontal direction.

28. The substrate processing apparatus according to claim 26, wherein the conveying machine includes a first driving mechanism that swirls the holding unit around its axis in the horizontal direction and the direction perpendicular to the conveyance direction and a second driving mechanism that swirls the holding unit around its axis in the conveyance direction.

29. The substrate processing apparatus according to claim 26, wherein the conveying machine includes a third driving mechanism that swirls the holding unit around its axis in a vertical direction.
